(19) United States
(12) Patent Application Publication
(10) Pub. No.: US 2016/0056397 A1
(43) Pub. Date: Feb. 25, 2016

(54) Non-Polar Solvents As An Adhesion Promoter Additive In PEDOT/PSS Dispersions

(71) Applicant: HERAEUS DEUTSCHLAND GMBH & CO. KG, Hanau (DE)

(72) Inventors: Stefan SCHUMANN, Köln (DE); Andreas ELSCHNER, Mülheim an der Ruhr (DE); Detlef GAISER, Köln (DE); Wilfried LÖVENICH, Bergisch Gladbach (DE); Daniel VOIGHT, Pulheim (DE)

(21) Appl. No.: 14/780,145

(22) PCT Filed: Mar. 27, 2014
(86) PCT No.: PCT/EP2014/000829

§ 371 Date: Sep. 25, 2015

Related U.S. Application Data
(60) Provisional application No. 61/827,130, filed on May 24, 2013.
(60) Provisional application No. 61/819,070, filed on May 3, 2013.

(30) Foreign Application Priority Data
Mar. 29, 2013 (DE) 10 2013 005 436.2
May 21, 2013 (DE) 10 2013 008 460.1

(51) Int. Cl. H01L 51/42; H01L 51/00; H01L 51/44

(52) U.S. Cl. CPC H01L 51/4253; H01L 51/441; H01L 51/0021; H01L 51/0036; H01L 51/005; H01L 51/0037

(57) ABSTRACT

Described is a process for the preparation of a layered body, the process comprising the steps: I) providing a photoactive layer; II) superimposing the photoactive layer with a coating composition comprising a) an electrically conductive polymer, b) an organic solvent; and III) at least partially removing the organic solvent b) from the composition obtaining an electrically conductive layer superimposing the photoactive layer. Also described is a layered body obtained by this process, a layered body, an organic photovoltaic cell, a solar cell module, a composition, and the use of a composition.

### CROSS-REFERENCE TO RELATED APPLICATIONS

This is application is the National Stage Entry of PCT/EP2014/000829, filed Mar. 27, 2014, which claims priority to German Patent Application 10 2013 005 436.2, filed on Mar. 29, 2013, U.S. Provisional Application Ser. No. 61/819,070, filed May 3, 2013, German Patent Application 10 2013 008 460.1, filed May 21, 2013, and U.S. Provisional Application Ser. No. 61/827,130, filed May 24, 2013, the disclosures of which are incorporated herein by reference in their entireties.

### TECHNICAL FIELD

The present invention relates to a process for the production of a layered body, the layered body obtainable by this process, a layered body, an organic photovoltaic cell, a solar cell module, a dispersion and the use of a dispersion.

### BACKGROUND

In the field of renewable energy, in recent years the organic photovoltaic (OPV) cell has developed into a very promising source of electricity by utilization of solar energy. Compared with commercially obtainable inorganic solar cells, typically silicon cells, OPV cells are based on organic components, and are extremely thin, lightweight and flexible. Low material and production costs in the reel-to-reel process and a very short amortization period of the production energy expended of only a few months show the market potential of this technology.

By achieving the record efficiency of 12%, OPV technology demonstrates a successful development in the direction of market readiness. However, in order to achieve this it is equally important to ensure the long-term stability of the OPV cells for a long life. The long-term stability is influenced by many different factors, delamination of layers being one of the main causes of degradation of an OPV cell. (Jørgensen et al. in Adv. Mater. 2012 (24), pages 580-612). Delamination can be caused, inter alia, by mechanical action (bending of flexible substrates) and by environmental influences, such as e.g. penetration of moisture. This leads to a loss of contact area, creates space for contamination by water and oxygen, which attack the layers, or even leads to complete detachment of layers. In the OPV cell in the inverted structure (upper, exposed electrode is the hole electrode, see FIG. 1 for the structure) the interface of the poly-3,4-ethylenedioxythiophene (PEDOT)/polystyrenesulphonate (PSS) layer and the photoactive layer, e.g. poly-3-hexylthiophene (P3HT):phenyl-C61-butyric acid methyl ester (PCBM), has been identified as the critical point in the layered structure. A delamination of the layers at the interface can be explained by the weak adhesion of the layers. The adhesion of layers describes how well or firmly the two layers stick to one another. Specifically in combinations of hydrophilic and hydrophobic layers (large difference in the surface energy), the adhesion can be greatly impaired. This problem already becomes clear in the process for application of the aqueous PEDOT:PSS dispersion to the hydrophobic photoactive layer, wherein an adequate wetting and good film quality are achieved only by addition of very potent surfactants.

To date only very few approaches to solving this major problem of adhesion are known, none having achieved an only approximately satisfactory improvement in adhesion. Thus, DuPont et al. have attempted to achieve an increase in the adhesion energy by a heat treatment (“annealing”) of the PEDOT:PSS layer on P3HT:PCBM at a higher temperature than during drying (150° C.), the effect measured there being additionally dependent on the PCBM content in the film. (DuPont et al. in Solar Energy Materials & Solar Cells 2012 (97), pages 171-175). The critical temperature in this process, however, can have an adverse effect on the morphology and stability of the very temperature-sensitive photoactive layer (glass transition temperature, Tg value, melting of the layer), which can lead to a loss in efficiency and long-term stability. Nevertheless, these high temperatures still involve disadvantages for an OPV cell, in particular their polymers and their large-scale industrial production process. There, therefore, continues to be a need to be able to produce OPV cells more efficiently at lower temperatures.

In addition to the annealing approach described above, attempts have also been made to influence the adhesion and life of the cells in an advantageous manner by employing surfactants to reduce the surface tension of the PEDOT:PSS dispersion and for better wetting of the surface (Lim et al. in J. of Mater. Chem. 2012 (22), pages 25057-25064), or to improve the adhesion of the PEDOT:PSS layer by roughening the photoactive layer.

However, with none of the measures described above has it yet been possible to achieve a satisfactory adhesion of a PEDOT:PSS layer to the photoactive layer of an organic photovoltaic cell.

### SUMMARY

A first aspect of the invention is directed to a process. In a first embodiment, a process for the production of a layered body comprises the steps: I) providing a photoactive layer; II) superimposing the photoactive layer with a coating composition comprising a) an electrically conductive polymer, b) an organic solvent); and III) at least partially removing the organic solvent b) from the coating composition superimposed in process step II) to obtain an electrically conductive layer superimposed on the photoactive layer.

In a second embodiment, the process of the first embodiment is modified, wherein the coating composition further comprises a surfactant c).

In a third embodiment, the process of the second embodiment is modified, wherein the coating composition further comprises an adhesion promoter additive d) that is a further organic solvent which differs from component b) and component c) and is miscible with component b), wherein the photoactive layer is soluble in the adhesion promoter additive.

In a fourth embodiment, the process of the first through third embodiments is modified, wherein the photoactive layer is a non-polar layer.

In a fifth embodiment, the process of the first through fourth embodiments is modified, wherein the photoactive layer comprises hydrophobic compounds which are a mixture of poly-3-hexylthiophene and phenyl-C61-butyric acid-methyl ester (P3HT:PCBM).

In a sixth embodiment, the process of the first through fifth embodiments is modified, wherein the electrically conductive polymer a) is a cationic polythiophene, which is present in the form of ionic complexes of the cationic polythiophene and a polymeric anion as the counter-ion.

In a seventh embodiment, the process of the first through sixth embodiments is modified, wherein the conductive polymer a) is present in the form of ionic complexes of poly(3,4-ethylenedioxythiophene) and polystyrenesulphonic acid (PEDOT:PSS).

In an eighth embodiment, the process of first through seventh embodiments is modified, wherein the organic solvent b) is selected from the group consisting of methanol, ethanol, 1-propanol, 2-propanol, 1,2-propanediol, 1,3-propanediol, ethylene glycol, diethylene glycol, propylene glycol, dipropylene glycol, glycerol, and mixtures of two or more thereof.

In a ninth embodiment, the process of the second through eighth embodiments is modified, wherein the surfactant c) is a nonionic surfactant.

In a tenth embodiment, the process of the third through ninth embodiments is modified, wherein the adhesion promoter additive d) is an aromatic compound in which one or more hydrogen atoms can optionally be replaced by halogen atoms.

In an eleventh embodiment, the process of the third through tenth embodiments is modified, wherein the adhesion promoter additive d) is selected from the group consisting of acetone, xylene, styrene, anisole, toluene, nitrobenzene, benzene, cyclohexane, tetrahydrofuran, chloronaphthalene, chlorobenzene, derivatives thereof, and mixtures of two or more thereof.

In a twelfth embodiment, the process of the first through eleventh embodiments is modified, wherein the coating composition of step II) is obtained by a process comprising the steps: IIa) providing a composition A comprising the conductive polymer a) and the organic solvent b); IIb) providing a composition B comprising the surfactant c) and a first auxiliary solvent; IIc) providing a composition C comprising the adhesion promoter additive d) and a second auxiliary solvent; IId) mixing compositions A, B and C in any desired sequence.

In a thirteenth embodiment, the process of the third through twelfth embodiments is modified, wherein the coating composition of step II) comprises, in each case based on the total weight of the composition: 0.4 to 1 wt. % of the conductive polymer a); 78 to 96 wt. % of the organic solvent b); 0.1 to 1.1 wt % of the surfactant c); 1 to 15 wt % of the adhesion promoter additive d); and 0 to 15 wt. % of one or more auxiliary substances.

In a fourteenth embodiment, the process of the first through thirteenth embodiments is modified, wherein the coating composition of step II) comprises, based on the total weight of the coating composition, less than 6 wt. % of water.

A second aspect of the invention is directed to a layered body. In a fifteenth embodiment, a layered body is obtained by the process of the first through fourteenth embodiments.

In a sixteenth embodiment, the layered body of the fifteenth embodiment is modified, comprising i) the photoactive layer comprising at least one hydrophobic compound; ii) the conductive layer comprising a conductive polymer and superimposed on the photoactive layer; and iii) an intermediate layer located between the photoactive layer and the conductive layer, the intermediate layer comprising a mixture of the conductive polymer and the at least one hydrophobic compound.

In a seventeenth embodiment, the layered body of the sixteenth embodiment is modified, wherein the photoactive layer comprises less conductive polymer from the conductive layer than the intermediate layer and the conductive layer comprises less of the at least one hydrophobic compound from the photoactive layer than the intermediate layer.

A third aspect of the present invention is directed to a layered body. In an eighteenth embodiment, a layered body comprises: i) a photoactive layer comprising at least one hydrophobic compound; ii) a conductive layer comprising a conductive polymer and superimposed on the photoactive layer; and iii) an intermediate layer located between the photoactive layer and the conductive layer and comprising a mixture of the conductive polymer and the at least one hydrophobic compound from.

In a nineteenth embodiment, the layered body of the eighteenth embodiment is modified, wherein the photoactive layer comprises less conductive polymer than the intermediate layer and the conductive layer comprises less of the at least one hydrophobic compound than the intermediate layer.

In a twentieth embodiment, the layered body of the eighteenth and nineteenth embodiment is modified, wherein the photoactive layer is a non-polar layer.

In a twenty-first embodiment, the layered body of the eighteenth through twentieth embodiments is modified, wherein the photoactive layer comprises hydrophobic compounds which are a mixture of poly-3-hexylthiophene and phenyl-C61-butyric acid-methyl ester (P3HT:PCBM).

In a twenty-second embodiment, the layered body of the fifteenth through seventeenth embodiments is modified, wherein the conductive polymer a) in the coating composition of step II) is a cationic polythiophene, which is present in the form of ionic complexes of the cationic polythiophene and a polymeric anion as the counter-ion.

In a twenty-third embodiment, the layered body of the eighteenth through twenty-second embodiments is modified, wherein the conductive polymer is present in the form of ionic complexes of poly(3,4-ethylenedioxythiophene) and polystyrenesulphonic acid (PEDOT:PSS).

In a twenty-fourth embodiment, the layered body of the eighteenth through twenty-third embodiments is modified, wherein the area of the conductive layer removed in the “cross-cut tape test” is less than 5%.

A fourth aspect of the present invention is directed to an organic photovoltaic cell. In a twenty-fifth embodiment, an organic photovoltaic cell comprises the layered body of the fifteenth through twenty-fourth embodiments.

In a twenty-sixth embodiment, the organic photovoltaic cell of the twenty-fifth embodiment is modified, comprising an anode; the layered body; optionally, an electron transport layer; and a cathode.

A fifth aspect of the present invention is directed to a solar cell module. In a twenty-seventh embodiment, a solar cell module, comprises at least one organic photovoltaic cell of the twenty-fifth or twenty-sixth embodiment.

A sixth aspect of the present invention is directed to a composition. In a twenty-eighth embodiment, a composition comprises, based on the total weight of the composition: 0.4 to 0.7 wt. % of PEDOT:PSS; 78 to 96 wt. % of an organic solvent selected from the group consisting of ethylene glycol, propanediol, ethanol, and mixtures of two or more thereof; 0.1 to 1.1 wt % of a surfactant; 1 to 15 wt. % of an adhesion promoter additive selected from the group consisting of xylene, toluene, styrene, anisole, cyclohexane, tetrahydrofuran, chlorobenzene, dichlorobenzene, and mixtures of two or more thereof; and 0 to 15 wt. % of one or more auxiliary substances.

In a twenty-ninth embodiment, the composition of the twenty-eighth embodiment is modified, wherein the composition comprises less than 6 wt. % of water.

A seventh aspect of the invention is directed to a P3HT:PCBM layer. In a thirtieth embodiment, a P3HT:PCBM layer has a conductive layer comprising the composition of the twenty-eighth or twenty-ninth embodiments.

In a thirty-first embodiment, the composition of the twenty-eighth embodiment is modified, wherein the weight of PEDOT:PSS is in a range of from 1:2 to 1:6.

An eighth aspect of the present invention is directed to a conductive film. In a thirty-second embodiment, a conductive film is formed from the composition of of the twenty-eighth embodiment, wherein the conductive film has a specific resistance of less than 10,000 Ω·cm.

### BRIEF DESCRIPTION OF DRAWINGS

FIG. 1 shows a diagram of the layer sequence through a layered body according to one or more embodiments;

FIG. 2 shows a diagram of the layer sequence through an organic photovoltaic cell according to one or more embodiments;

FIG. 3a shows a diagram of the layer sequence through an organic photovoltaic cell according to one or more embodiments;

FIG. 3b shows a diagram of the layer sequence through an organic photovoltaic cell according to one or more embodiments;

FIG. 4 shows the manner in which the “cross-cut tape” test is carried out for determination of the strength of the adhesion according to one or more embodiments; and

FIG. 5 shows how the result of the “cross-cut tape” test is evaluated analytically according to one or more embodiments.

### DETAILED DESCRIPTION

The present invention was therefore based on the object of overcoming the disadvantages resulting from the prior art in connection with the lack of adhesion of layers of conductive polymers, in particular of PEDOT:PSS layers, to photoactive layers, in particular to non-polar, photoactive layers comprising P3HT:PCBM.

In particular, the present invention was based on the object of providing a process for the production of a layered body which can be used in particular in the production of organic photovoltaic cells and with which in particular the mechanical stability and the long-term stability of the organic photovoltaic cells can be improved. By the process according to the invention it should be possible to produce layered bodies comprising a photoactive layer, in particular a non-polar photoactive layer comprising P3HT:PCBM, on to which a layer of a conductive polymer, in particular a PEDOT:PSS layer, is applied, whereby in particular the adhesion of the layer of the conductive polymer to the photoactive layer should be improved by the process compared with the processes known from the prior art for the production of such layered bodies.

The present invention was also based on the object of providing a layered body which can be employed, for example, in an organic photovoltaic cell and comprises a photoactive layer, in particular a non-polar photoactive layer comprising P3HT:PCBM, on to which a layer of a conductive polymer, in particular a PEDOT:PSS layer, is applied, wherein this layered body is distinguished by an improved adhesion of the layer of the conductive polymer to the photoactive layer compared with the corresponding layered bodies known from the prior art.

A contribution towards achieving at least one of the abovementioned objects is made by a process for the production of a layered body, at least comprising the process steps:
I) the provision of a photoactive layer;
II) the superimposing of the photoactive layer with a coating composition at least comprising
   a) an electrically conductive polymer,
   b) an organic solvent,
III) the at least partial removal of the organic solvent b) from the composition superimposed in process step II) obtaining an electrically conductive layer covering the photoactive layer.

In the process according to the invention for the production of a layered body, it is preferable for the coating composition to comprise c) a surfactant.

In the process according to the invention for the production of a layered body, it is moreover preferable for the coating composition to comprise, as an adhesion promoter additive, d) a further organic solvent which differs from component b) and component c) and is miscible with component b), the photoactive layer (3) being soluble in this adhesion promoter additive.

In the process according to the invention for the production of a layered body, it is furthermore preferable for the photoactive layer to be a non-polar layer. In one embodiment according to the invention, the photoactive layer is called a non-polar layer.

A further contribution towards achieving at least one of the abovementioned objects is made by a process for the production of a layered body, at least comprising the process steps:
I) the provision of a photoactive layer comprising at least one hydrophobic compound;
II) the superimposing of, preferably application to, the photoactive layer with a composition at least comprising
   a) an electrically conductive polymer,
   b) an organic solvent,
   c) a surfactant, and
   d) a further organic solvent, as an adhesion promoter additive, which differs from component b) and component c) and is miscible with component b), the at least one hydrophobic compound of the photoactive layer being soluble in this adhesion promoter additive;
III) the at least partial removal of the organic solvent b) from the composition superimposed in process step II) obtaining an electrically conductive layer applied to or covering the photoactive layer.

It has been found, surprisingly, that by the addition of the adhesion promoter additive b) a clear improvement in the adhesion of the conductive layer, in particular a conductive layer comprising PEDOT:PSS, to the photoactive layer, in particular to a photoactive layer comprising P3HT:PCBM, can be achieved. With the improved adhesion, the delamination of the layers is prevented and the long-term stability of the layered body, for example in an OPV cell, is increased. Furthermore, more robustness is imparted to the layered body, which is indispensible under mechanical stress, such as occurs, for example, during bending (flexible substrates) and during the production process (“reel-to-reel” process). The solution approach via the adhesion promoter additive b) is not possible with conventional water-based PEDOT:PSS dispersions, since the solubility of the adhesion promoter additive (active solvent in the adhesion process) in water is much too low. A brief, slight superficial dissolving of the underlying photoactive layer by the adhesion promoter additive d) is postulated. As a result, during application of the composition comprising the conductive polymer, a partial mixing of the dissolved components at the interface is possible. This can have the effect on the one hand of roughening of the surface, and on the other hand of partial diffusing of strands of the conductive polymer, preferably of PEDOT polymer strands, into the underlying photoactive layer or of the hydrophobic compounds of the photoactive layer, preferably of P3HT strands and PCBM, into the conductive layer. In each case, a significant improvement in the adhesion of the layer of the conductive polymer on the underlying photoactive layer is to be found. The surfaces should ideally be superficially dissolved by the adhesion promoter additive d). The additive can be adapted according to the surface to be coated.

Photoactive layers are understood here preferably as meaning layers which can convert radiation, preferably with contents of visible light, into electrical energy, optionally by means of additional layers. Photoactivity often manifests itself in an external quantum efficiency of more than 10%. The quantum efficiency is conventionally determined from the ratio of the wavelength-dependent photocurrent of the OPV cell with respect to a calibrated reference cell (e.g. calibrated and certified by the Fraunhofer Institute Freiburg) with a quantum yield calibrated over the entire wavelength spectrum to be measured. In this context, the photoactive areas of the particular cells must be precisely defined and standardized via a shadow mask. A white light source, such as e.g. a xenon arc lamp, conventionally serves as the light source, it being necessary for the measurement to be carried out with exactly the same light source, but otherwise being independent of the source. The spectral resolution typically takes place via a monochromator or a filter system.

A further organic solvent which is miscible with component b) can exist in particular if this further organic solvent results in a homogeneous solution with component b). In this context in particular, component b) does not precipitate out in the further organic solvent or is not present in this as a solid in the form of a dispersion.

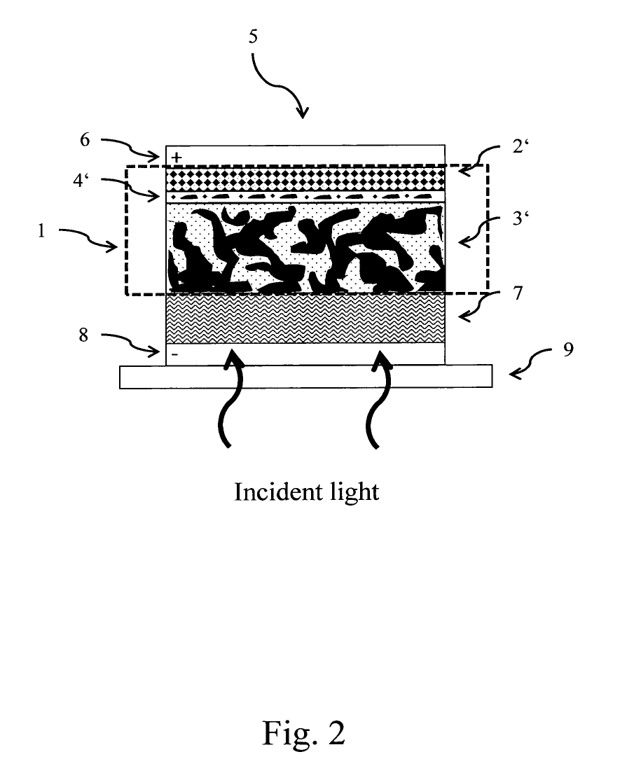

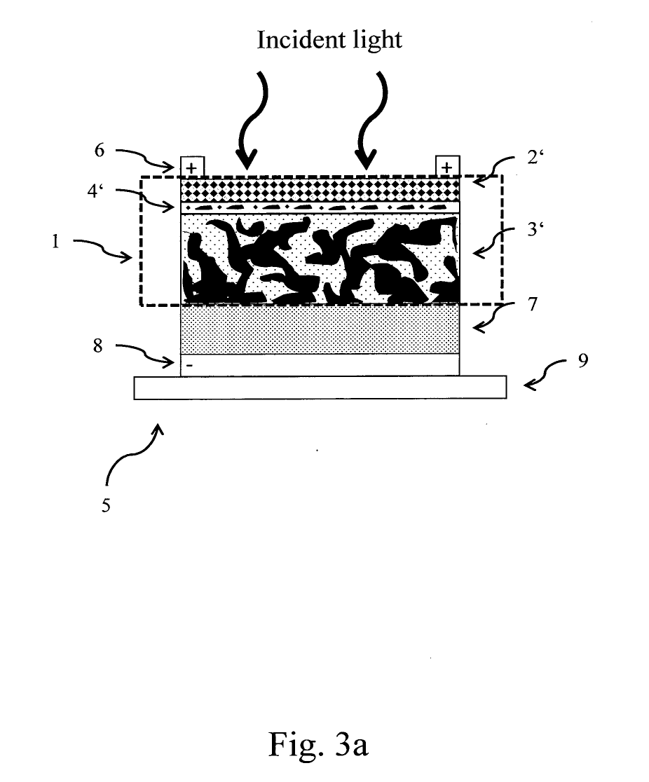

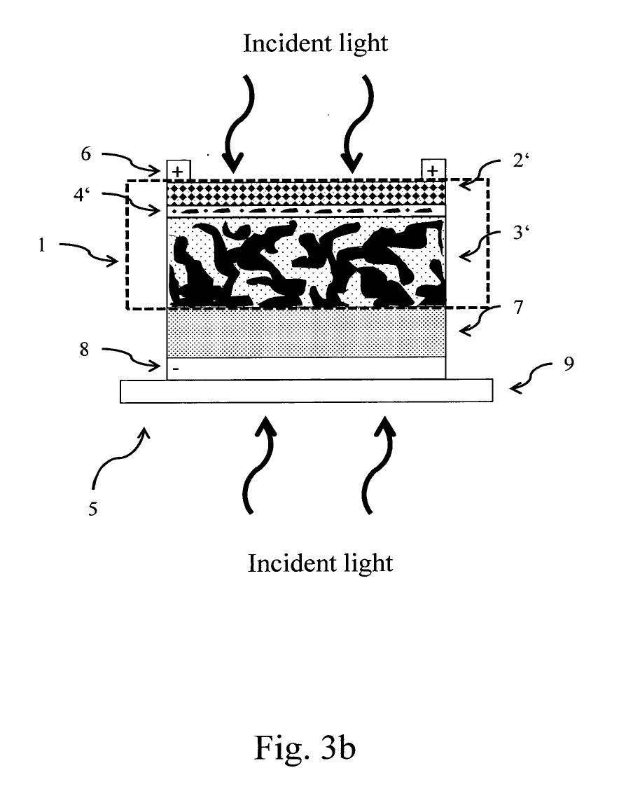

The invention brings a significant improvement in particular in the field of OPV cells in the inverted structure (see FIGS. 2 and 3), since the interface between the photoactive layer (P3HT:PCBM) and the PEDOT:PSS has been identified as the critical point for the mechanical stability and the long-term stability of the OPV cell. However, the invention can also be used for coating other photoactive surfaces, e.g. in the coating of films with hydrophobic surfaces.

In process step I) of the process according to the invention, a photoactive layer comprising at least one hydrophobic compound is first provided, this photoactive layer preferably being a photoactive layer such as is conventionally employed in organic solar cells.

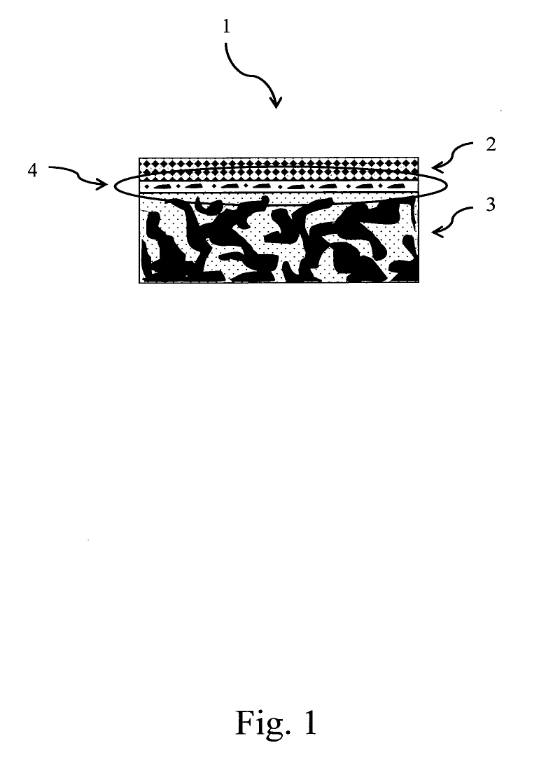

Preferably, such a photoactive layer comprises an electron donor material and an electron acceptor material, it being possible for these two materials to be present in the form of a mixture, and also in a common layer by an intermeshing of regions, preferably as a comb structure, of the two materials, (cf. FIG. 1 in An Amorphous Mesophase Generated By Thermal Annealing for High-Performance Organic Photovoltaic Devices, Hideyhki Tanaka et al., Adv. Matter 2012, 24, 3521-3525) or nanostructured in a shared layer, or in two separate layers following one another, one of which contains the electron donor material and the other the electron acceptor material. The electron donor material can be a conductive polymer material of the p-type.

Possible electron donor materials are, for example, poly(3-alkylthiophenes), such as P3HT (poly(3-hexylthiophene)), polysiloxanecarbazole, polyaniline, polyethylene oxide, (poly(l-methoxy-4-(O-dispersion red 1)-2,5-phenylenevinylene), MEH-PPV (poly-[2-methoxy-5-(2′-ethoxyhexyloxy)-1,4-phenylenevinylene]); MDMO-PPV (poly[2-methoxy-5-3(3′,7′-dimethyloctyloxy)-1,4-phenylenevinylene]); PFDTBT (poly-(2,7-(9,9-dioctyl)-fluorene-alt-5,5-(4′,7′-di-2-thienyl-2′,1′,3′-benzothiadiazole)); PCPDTBT (poly[N′,O′-heptadecanyl-2,7-carbazole-alt-5,5-(4′,7′,-di-2-thienyl-2′,1′,3′-benzothiazole)], PCDTBT (poly[N-9′-heptadecanyl-2,7-carbazole-alt-5,5-(4′,7′-di-2-thienyl-2′,1′,3″-benzothiadiazole)]), poly(4,4-dioctyldithieno(3,2-b: 2′,3′-d) silole)-2,6-diyl-alt-(2,1,3-benzothiadiazole)-4,7-diyl) (PSBTBT), polyindole, polycarbazole, polypyridiazine, polyisothianaphthalene, polyphenylene sulphide, polyvinylpyridine, oligo- and polythiophene, polyfluorene, polypyridine or derivatives thereof. Any desired combinations of at least two of the electron donor materials listed above, for example as a mixture or copolymer, can also be employed. The polymers described here have 10 and more recurring units. Oligomers have fewer than 10 and more than two recurring units. So-called “small molecules”, which are suitable in particular for reduced pressure vapour deposition, but can also be applied in solution, have one or two recurring units. Examples of small molecules are: thiophenes, merocyanines, polycyclic aromatic hydrocarbons (PAH), in particular anthracene, tetracene, pentacene, perylene; phthalocyanines, in metal-free form and with a metal centre; sub-phthalocyanines, with or without metal centres; naphthalocyanines, with or without metal centres; porphyrins, with or without metal centres; including their respective derivatives; or a combination of at least two, for example in a co-deposition. By way of example of small molecules, reference may be made to WO-A-2013/013765 A1, in which a number of suitable compounds, including synthesis thereof, are disclosed.

Possible electron acceptor materials (n-type) are, for example, fullerenes or derivatives thereof, such as, for example, C₆₀, C₇₀, PC₆₀BM (phenyl-C61-butyric acid-methyl ester), PC₇₀BM, nanocrystals, such as CdSe, carbon nanotubes, polybenzimidazole (PBI) nanorods or 3,4,9,10-perylenetetracarboxylic acid bisbenzimidazole (PTCBI). Further electron acceptor materials are zinc oxide, titanium oxide and other transition metal oxides, in particular as nanoparticles, nanorods or 3D networks of hierarchic structure.

According to the invention, it is particularly preferable for the photoactive layer to comprise a mixture of a non-polar electron donor material and a non-polar electron acceptor material, in particular a mixture of poly-3-hexylthiophene and phenyl-C61-butyric acid-methyl ester (P3HT:PCBM) as hydrophobic compounds:

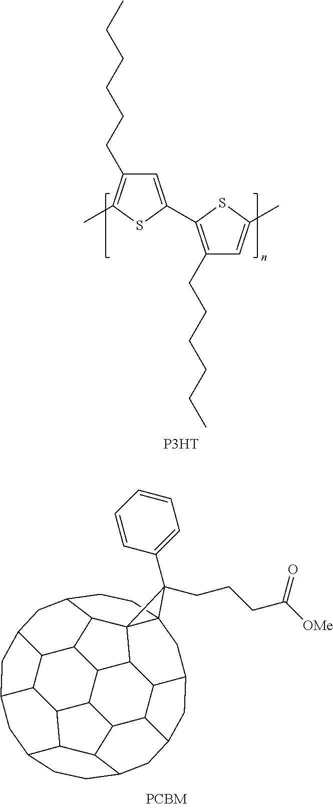

The mixing ratio of electron donor material to electron acceptor material in this context is preferably in a range of from 10:1 to 10:100 (based on the weight), particularly preferably 2:1 to 1:2, but is not limited thereto. Typical weight ratios are 1:1 to 1:0.8 P3HT:PCBM.

The thickness of the photoactive layer is preferably in a range of from <1 nm to 15 μm, preferably 5 nm to 2 μm. In this context, the photoactive, preferably photoactive layer can be produced on a suitable substrate using a general deposition process or coating process, for example using spraying on, rotational coating, immersion, brushing, printing on, a knife coating process, sputtering, wet deposition, for example as a chemical and/or thermal process, reduced pressure vapour deposition, chemical vapour deposition, a melting process or electrophoresis.

In process step II), the photoactive layer is then covered with the composition at least comprising components a), b), c) and d), this composition preferably being a dispersion.

The conductive polymer a) is preferably a polythiophene, particularly preferably a polythiophene having recurring units of the general formula (i) or (ii) or a combination of units of the general formulae (i) and (ii), very particularly preferably a polythiophene having recurring units of the general formula (ii)

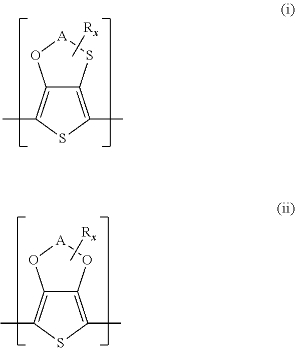

wherein
A represents an optionally substituted C₁-C₅-alkylene radical,
R represents a linear or branched, optionally substituted C₁-C₁₈-alkyl radical, an optionally substituted C₅-C₁₂-cycloalkyl radical, an optionally substituted C₆-C₁₄-aryl radical, an optionally substituted C₇-C₁₈-aralkyl radical, an optionally substituted C₁-C₄-hydroxyalkyl radical or a hydroxyl radical,
x represents an integer from 0 to 8 and
   in the case where several radicals R are bonded to A, these can be identical or different.

The general formulae (i) and (ii) are to be understood as meaning that x substituents R can be bonded to the alkylene radical A.

Polythiophenes having recurring units of the general formula (ii) wherein A represents an optionally substituted C₂-C₃-alkylene radical and x represents 0 or 1 are particularly preferred.

In the context of the invention, the prefix “poly” is to be understood as meaning that the polymer or polythiophene comprises more than one identical or different recurring units of the general formulae (i) and (ii). In addition to the recurring units of the general formulae (i) and/or (ii), the polythiophenes can optionally also comprise other recurring units, but it is preferable for at least 50%, particularly preferably at least 75% and most preferably at least 95% of all the recurring units of the polythiophene to have the general formula (i) and/or (ii), preferably the general formula (ii). The percentage figures stated above are intended here to express the numerical content of the units of the structural formula (i) and (ii) in the total number of monomer units in the foreign-doped conductive polymer. The polythiophenes comprise a total of n recurring units of the general formula (i) and/or (ii), preferably of the general formula (ii), wherein n is an integer from 2 to 2,000, preferably 2 to 100. The recurring units of the general formula (i) and/or (ii), preferably of the general formula (ii), can in each case be identical or different within a polythiophene. Polythiophenes having in each case identical recurring units of the general formula (ii) are preferred.

According to a very particular embodiment of the process according to the invention, at least 50%, particularly preferably at least 75%, still more preferably at least 95% and most preferably 100% of all the recurring units of the polythiophene are 3,4-ethylenedioxythiophene units (i.e. the most preferred conductive polymer a) is poly(3,4-ethylenedioxythiophene)).

The polythiophenes preferably in each case carry H on the end groups.

In the context of the invention, C₁-C₅-alkylene radicals A are preferably methylene, ethylene, n-propylene, n-butylene or n-pentylene. C₁-C₁₈-Alkyl radicals R preferably represent linear or branched C₁-C₁₈-alkyl radicals, such as methyl, ethyl, n- or iso-propyl, n-, iso-, sec- or tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-hexadecyl or n-octadecyl, C₅-C₁₂-cycloalkyl radicals R represent, for example, cyclopentyl, cyclohexyl, cycloheptyl, cyclooctyl, cyclononyl or cyclodecyl, C₅-C₁₄-aryl radicals R represent, for example, phenyl or naphthyl, and C₇-C₁₈-aralkyl radicals R represent, for example, benzyl, o-, m-, p-Tolyl, 2,3-, 2,4-, 2,5-, 2,6-, 3,4-, 3,5-xylyl or mesityl. The preceding list serves to illustrate the invention by way of example and is not to be considered conclusive.

In the context of the invention, numerous organic groups are possible as optionally further substituents of the radicals A and/or of the radicals R, for example alkyl, cycloalkyl, aryl, aralkyl, alkoxy, halogen, ether, thioether, disulphide, sulphoxide, sulphone, sulphonate, amino, aldehyde, keto, carboxylic acid ester, carboxylic acid, carbonate, carboxylate, cyano, alkylsilane and alkoxysilane groups and carboxamide groups.

The polythiophenes are preferably cationic, “cationic” relating only to the charges on the polythiophene main chain. The positive charges are not shown in the formulae, since their precise number and position cannot be determined absolutely. However, the number of positive charges is at least 1 and at most n, where n is the total number of all recurring units (identical or different) within the polythiophene.

To compensate the positive charge, the cationic polythiophenes require anions as counter-ions, the counter-ions preferably being polymeric anions (polyanions). It is preferable in this connection for the conductive polymer a) in the composition employed in process step II) to be a cationic polythiophene, which is present in the form of ionic complexes of the cationic polythiophene and a polymeric anion as the counter-ion. It is very particularly preferable for the conductive polymer a) to be present in the form of ionic complexes of poly(3,4-ethylenedioxythiophene) and polystyrenesulphonic acid (PEDOT:PSS).

Polyanions are preferable to monomeric anions as counter-ions, since they contribute towards film formation and because of their size lead to electrically conductive films which are thermally stable. Polyanions here can be, for example, anions of polymeric carboxylic acids, such as polyacrylic acids, polymethacrylic acid or polymaleic acids, or of polymeric sulphonic acids, such as polystyrenesulphonic acids and polyvinylsulphonic acids. These polycarboxylic and -sulphonic acids can also be copolymers of vinylcarboxylic and vinylsulphonic acids with other polymerizable monomers, such as acrylic acid esters and styrene. Particularly preferably, the solid electrolyte comprises an anion of a polymeric carboxylic or sulphonic acid for compensation of the positive charge of the polythiophene.

The anion of polystyrenesulphonic acid (PSS), which, if a polythiophene is used, in particular poly(3,4-ethylenedioxythiophene), is preferably present—as already stated above—bonded as a complex in the form of the PEDOT:PSS ionic complexes known from the prior art, is particularly preferred as the polyanion. Such ionic complexes are obtainable by polymerizing the thiophene monomers, preferably 3,4-ethylenedioxythiophene, oxidatively in aqueous solution in the presence of polystyrenesulphonic acid. Details of this are to be found, for example, in chapter 9.1.3 in “PEDOT.Principles and Applications of an Intrinsically Conductive Polymer”, Elschner et al., CRC Press (2011).

The molecular weight of the polyacids which supply the polyanions is preferably 1,000 to 2,000,000, particularly preferably 2,000 to 500,000. The polyacids or their alkali metal salts are commercially obtainable, e.g. polystyrenesulphonic acids and polyacrylic acids, or can be prepared by known processes (see e.g. Houben Weyl, Methoden der organischen Chemie, vol. E 20 Makromolekulare Stoffe, part 2, (1987), p. 1141 et seq.).

The ionic complexes of polythiophenes and polyanions, in particular the PEDOT:PSS ionic complexes, are preferably present in the composition employed in process step II) in the form of particles. These particles in the composition preferably have a specific resistance of less than 10,000 ohm·cm.

The particles in the composition employed in process step II) preferably have a diameter d₅₀ in a range of from 1 to 100 nm, preferably in a range of from 1 to 60 nm and particularly preferably in a range of from 5 to 40 nm. The d₅₀ value of the diameter distribution says in this context that 50% of the total weight of all the particles in the dispersion can be assigned to those particles which have a diameter of less than or equal to the d₅₀ value. The diameter of the particles is determined via an ultracentrifuge measurement. The general procedure is described in Colloid Polym. Sci. 267, 1113-1116 (1989).

The composition employed in process step II) comprises as component b) an organic solvent, this organic solvent b) preferably being a C₁-C₄-mono- or C₁-C₄-dialcohol, particularly preferably a C₁-C₄-mono- or C₁-C₄-dialcohol or C₁-C₄-trialcohols chosen from the group consisting of methanol, ethanol, 1-propanol, 2-propanol, 1,2-propanediol, 1,3-propanediol, ethylene glycol, diethylene glycol, propylene glycol, dipropylene glycol, glycerol and a mixture of two or more of these organic solvents. Organic esters, preferably with one or more of the abovementioned alcohols, represent a further group of solvents according to the invention. Solvents which are advantageous according to the invention are suitable in particular for redissolving electrically conductive polymers, preferably from water or aqueous solutions. Such solvents, including the redissolving, are described, for example, in WO 99/34371 (redissolved paste) and WO 02/072660 (redissolving process). According to this, organic, water-miscible solvents are preferred. It is furthermore preferable for the possible solvents to have a boiling point of more than 100° C.

The composition employed in process step II) comprises as component c) a surfactant, it being possible for all surfactant classes (i.e. anionic surfactants, cationic surfactants, amphoteric surfactants and nonionic surfactants) or also mixture of surfactants of different surfactant classes to be employed as the surfactant. The use of nonionic surfactants is preferred.

Examples of suitable surfactants are halogenated, in particular fluorinated surfactants, glycols, in particular polyalkylene glycols, such as polyethylene glycol, polypropylene glycol or acetylene glycols, alcohols or siloxanes, in particular polysiloxanes, specifically so-called “gemini surfactants” based on polysiloxanes, which are distinguished in that at least two hydrophobic side chains and two ionic or polar groups are bonded via a “spacer”. Such “gemini surfactants” are also called “bi-surfactants” in the literature (in this context see also “Eine neue Technologie: Das multifunktionelle siloxanhaltige Gemini-Tensid”; Struck et al.; technical article from Evonik Tego Chemie).

Concrete examples of surfactants suitable according to the invention which may be mentioned are:
ZONYL™ FSN (a 40 wt. % strength solution of F(CF₂CF₂)₁₋₉(CH₂CH₂O(CH₂CH₂O)ₓH in a 50 wt. % strength aqueous solution of isopropanol, wherein x=0 to about 25/marketed by DuPont);
ZONYL™ FSN 100 (F(CF₂CF₂)₁₋₉CH₂CH₂O(CH₂CH₂O)ₓH, wherein x=0 to about 25/marketed by DuPont);
ZONYL™ FS300 (a 40 wt. % strength aqueous solution of a fluoro-surfactant/marketed by DuPont);
ZONYL™ FSO (a 50 wt. % strength solution of the ethoxylated non-ionic fluoro-surfactant of the formula F(CF₂CF₂)₁₋₇CH₂CH₂O(CH₂CH₂O)_{y}H, wherein y=0 to about 15, in a 50 wt. % strength aqueous solution of ethylene glycol/marketed by DuPont);
ZONYL™ FSO 100 (a mixture of ethoxylated non-ionic fluoro-surfactant of the formula F(CF₂CF₂)₁₋₇CH₂CH₂O(CH₂CH₂O)_{y}H, wherein y=0 to about 15/marketed by DuPont);
ZONYL™ 7950 (a fluoro-surfactant from DuPont);
ZONYL™ FSA (a 25 wt. % strength solution of F(CF₂CF₂)₁₋₉CH₂CH₂SCH₂CH₂COOLi in a 50 wt. % strength aqueous solution of isopropanol/marketed by DuPont);
ZONYL™ FSE (a 14 wt. % strength solution of [F(CF₂CF₂)₁₋₇CH₂CH₂O]ₓP(O)(ONH₄)_{y}, wherein x=1 or 2, y=2 or 1 and x+y=3, in a 70 wt. % strength aqueous solution of ethylene glycol/marketed by DuPont);
ZONYL™ FSJ (a 40 wt. % strength solution of a mixture of F(CF₂CF₂)₁₋₇CH₂CH₂O]ₓP(O)(ONH₄)_{y}, wherein x=1 or 2, y=2 or 1 and x+y=3, and a hydrocarbon surfactant in a 25 wt. % strength aqueous solution of isopropanol/marketed by DuPont);
ZONYL™ FSP, a 35 wt. % strength solution of [F(CF₂CF₂)₁₋₇CH₂CH₂O]ₓP(O)(ONH₄)_{y}, wherein x=1 or 2, y=2 or 1 and x+y=3, in a 69.2 wt. % strength aqueous solution of isopropanol/marketed by DuPont;
ZONYL™ UR ([F(CF₂CF₂)₁₋₇CH₂CH₂O]ₓP(O)(OH)_{y}, wherein x=1 or 2, y=2 or 1 and x+y=3/marketed by DuPont);
ZONYL™ TBS: a 33 wt. % strength solution of F(CF₂CF₂)₃₋₈CH₂CH₂SO₃H in a 4.5 wt. % strength aqueous solution of acetic acid/marketed by DuPont);
TEGOGLIDE™ 410 (a polysiloxane polymer copolymer surfactant/marketed by Goldschmidt);
TEGOWET™ (a polysiloxane/polyester copolymer surfactant/marketed by Goldschmidt);
FLUORAD™ FC431 (CF₃(CF₂)₇SO₂(C₂H₅)N—CH₂CO—(OCH₂CH₂)ₙOH/marketed by 3M);
FLUORAD™ FC126 (a mixture of the ammonium salts of perfluorocarboxylic acids/marketed by 3M);
FLUORAD™ FC430 (a 98.5% strength active aliphatic fluoro-ester surfactant from 3M);
Polyoxyethylene 10-lauryl ether;
SILWET™ H212 (copolymer from Momentive);
SURFINOL™ 104 (acetylenic diol from Air Products);
DYNOL™ 604 (Air Products);
TRITON™-X-100 (4-(1,1,3,3-tetramethylbutyl)phenylpolyethylene glycol from Dow);
TRITON™ XNA45S (Dow);
TEGO™Twin 4000 and TEGO™Twin 4100 (“gemini surfactants” from Evonik).

Of these surfactants, the use of “gemini surfactants”, in particular the “gemini surfactant” TEGO™Twin 4000, is very particularly preferred.

The composition employed in process step II) comprises as component d) a further organic solvent, as an adhesion promoter additive, which differs from component b) and component c) and is miscible with component b), this adhesion promoter additive being characterized in that the at least one hydrophobic compound of the photoactive layer is soluble (or at least partly soluble) in this adhesion promoter additive. It is furthermore advantageous to chose as the adhesion promoter additive d) a compound which is soluble in the organic solvent b) of the composition or miscible with this organic solvent b).

Adhesion promoter additives d) which are preferred according to the invention and have proved to be advantageous in particular in the case of P3HT and PCBM as hydrophobic compounds of the photoactive layer are aromatic compounds in which one or more hydrogen atoms can optionally be replaced by halogen atoms. Examples of suitable adhesion promoter additives d) which may be mentioned are, in particular, ketones, such as acetone; aromatics, preferably o-, m-, p-xylene, styrene, anisole, toluene, anisole, nitrobenzene, benzene, chloronaphthalene, monochlorobenzene, 1,2- and 1,3-dichlorobenzene, trichlorobenzene; halohydrocarbons, preferably chloroform; cyclic hydrocarbons, preferably tetrahydrofuran, cyclohexane; derivatives thereof; or mixture of at least two of these compounds. Further suitable adhesion promoter additives d) are mentioned in WO 2013/013765, page 47, lines 11 to 34.

In addition to components a), b), c) and d) described above, the composition employed in process step II) can also comprise further auxiliary substances e), such as, for example, binders, crosslinking agents, viscosity modifiers, pH regulators, additives which increase the conductivity, antioxidants, agents which modify work function or further auxiliary solvents which are required, for example, for homogeneous mixing of the individual components.

Possible pH regulators are acids and bases, those which do not influence film production being preferred. Possible bases are amines; alkylamines, preferably 2-(dimethylamino)ethanol, 2,2′-iminodiethanol or 2,2′2″-nitrilotriethanol, pentylamine; ammonia solution and alkali metal hydroxides.

The composition employed in process step II) is preferably obtainable by a process comprising the process steps:
IIa) the provision of a composition A comprising the conductive polymer a) and the organic solvent b);
IIb) the provision of a composition B comprising the surfactant c) and preferably a first auxiliary solvent;
IIc) the provision of a composition C comprising the adhesion promoter additive d) and preferably a second auxiliary solvent;
IId) the mixing of compositions A, B and C in any desired sequence.

The sequence of process steps IIa), IIb) and IIc) in this context is irrelevant.

A composition A comprising the conductive polymer a) and the organic solvent b) is first provided in process step IIa). In the case of conductive polymers based on PEDOT:PSS ionic complexes, in this context these ionic complexes can first be prepared in the form of aqueous dispersions, as can be seen by the person skilled in the art, for example, from chapter 9.1.3 in “PEDOT.Principles and Applications of an Intrinsically Conductive Polymer”, Elschner et al., CRC Press (2011). In the aqueous PEDOT:PSS dispersions obtainable in this manner, the water can be replaced by the organic solvent b), as is described, for example, in US 2003/0006401 A1 or WO-A-02/072660.

In process step IIb), a composition B comprising the surfactant c) is provided, and optionally can already be employed in the form in which it is commercially obtainable. Preferably, however, the surfactant c) is mixed with a first auxiliary solvent, organic auxiliary solvents, in particular alcohols, having proved to be advantageous as the first, preferably organic auxiliary solvent. Possible solvents are, in particular, alcohols, such as n-propanol, iso-propanol, n-pentanol, n-octanol or mixtures of these.

In process step IIc), a composition C comprising the adhesion promoter additive d) and preferably a second, preferably organic auxiliary solvent is provided. Alcohols in particular have also proved advantageous as the second auxiliary solvent here, possible alcohols in turn being n-propanol, iso-propanol, n-pentanol, n-octanol or mixtures of these. In view of the film formation, iso-propanol has proved to be particularly advantageous (both as the first auxiliary solvent for the surfactant c) and as the second auxiliary solvent for the adhesion promoter additive d)). For the preparation of composition C, the adhesion promoter additive d) and the auxiliary solvent are mixed with one another in a weight ratio of adhesion promoter additive d) organic auxiliary solvent in a range of from 1:9 to 1:1, the components being mixed in any desired sequence with constant stirring. The mixture is then stirred until a homogeneous intimate mixture of the components is present.

In process step IId), compositions A, B and C are then mixed in any desired sequence. This mixing particularly preferably takes place such that composition A is first initially introduced into the mixing vessel, preferably in the form of a dispersion, and composition B and composition C are then added in the given sequence, with constant stirring. The mixture is then stirred until a homogeneous intimate mixture of the components is present.

In this context, composition B is preferably metered into the vessel in an amount such that a surfactant concentration in a range of from 0.1 to 1.1 wt. %, particularly preferably in a range of from 0.1 to 0.5 wt. %, in each case based on the total weight of the composition employed in process step II), is established, while composition C is preferably metered into the vessel in an amount such that a concentration of the adhesion promoter additive d) in a range of from 1 to 15 wt. %, particularly preferably in a range of from 2.5 to 12.5 wt. %, in each case based on the total weight of the composition employed in process step II), is established. The auxiliary solvents, preferably iso-propanol, dilute the batch, depending on the solution recipe, with concentrations of less than 1 wt. % to about 15 wt. %.

The process for the preparation of the composition employed in process step II) may further comprise a post-processing step IIe) comprising the process steps:
IIea) treating the mixture obtained in process step IId) by filtration thereby obtaining a filtrate;
IIeb) treating the filtrate obtained in process step Ilea) with ultrasonic radiation.

By means of the post-processing several important parameters, such as viscosity, opacity/turbidity of the layer and filterability, can be significantly improved.

In process step Ilea) the mixture obtained in process step IId) by filtration preferably by means of depth filtration. For that purpose, cellulose-based filtration materials, in particular filtration materials based on a mixture of cellulose fibres, diatomaceous earth and perlite as they are available under the trade names Seitz® T 950, Seitz® T 1000, Seitz® T 1500, Seitz® T 2100, Seitz® T 2600, Seitz® T 3500 or Seitz® T 5500 from Pall Life Sciences, USA.

The thus obtained filtrate is then treated with ultrasonic radiation in process step IIeb). In this context it is preferred that the ultrasonic radiation is performed at a temperature in the range from 0 to 50° C., preferably 0 to 25° C., preferably under ice cooling of the dispersion, for a period of 15 minutes to 24 hours, preferably for 1 hour to 10 hours. It is particularly preferred to treat the filtrate with ultrasonic radiation until a certain maximum value of the viscosity, preferably a value of less than 100 mPas or 50 mPas or less, has been reached. The treatment of the filtrate with ultrasound radiation can be performed by hanging an ultrasound finger into the filtrate or by pumping the filtrate through an ultrasound flow cell. Here, the energy input may be between 10 and 1000 watts/liter (w/l) of the filtrate. The ultrasound frequency is preferably between 20 and 200 kHz.

The composition employed in process step II) preferably comprises, in each case based on the total weight of the composition,
0.1 to 5 wt. %, particularly preferably 0.4 to 3 wt. % and most preferably 0.5 to 1 wt. % of the conductive polymer a), particularly preferably PEDOT:PSS;
50 to <100 wt. %, particularly preferably 68 to 99 wt. % and most preferably 78 to 96 wt. % of the organic solvent b), particularly preferably chosen from the group consisting of ethylene glycol, propanediol, ethanol and mixtures of at least two of these;
0.1 to 1.1 wt. %, particularly preferably 0.1 to 0.5 wt. % and most preferably 0.2 to 0.4 wt. % of the surfactant c), particularly preferably a surfactant, preferably a “gemini surfactant”, based on siloxanes;
1 to 15 wt. %, particularly preferably 2.5 to 12.5 wt. % and most preferably 5 to 10 wt. % of the adhesion promoter additive d), particularly preferably dichlorobenzene;
0 to 15 wt. %, particularly preferably 0.5 to 10 wt. % and most preferably 5 to 10 wt. % of one or more auxiliary substances, particularly preferably iso-propanol as an auxiliary solvent.

In a further embodiment, the composition can first be prepared as described in process step II and then diluted again by addition of further solvent, preferably with an alcohol, for example at least one of the abovementioned alcohols. Dilutions by at least two-, preferably at least three- and particularly preferably at least four-fold are conceivable here. Dilutions up to 20-fold are often not exceeded.

It is furthermore preferable according to the invention for the composition employed in process step II) to have at least one, but preferably all of the following properties:
A) the composition comprises, based on the total weight of the composition, less than 6 wt. %, particularly preferably less than 4 wt. % and most preferably less than 2 wt. % of water;
B) the composition comprises ionic complexes of PEDOT:PSS as the conductive polymer a), the weight ratio of PEDOT:PSS in the composition being in a range of from 1:0.5 to 1:25, particularly preferably in a range of from 1:2 to 1:20 and most preferably in a range of from 1:2 to 1:6;
C) a conductive film formed from the composition is characterized by a specific resistance of less than 10,000 Ω·cm, particularly preferably less than 10 Ω·cm and most preferably of less than 1 Ω·cm.

Particularly advantageous compositions which can be employed in process step II) are characterized by the following properties or following combinations of properties: A), B), C), A)B), A)C), B)C) and A)B)C), the combination of properties A)B)C) being most preferred.

The covering can be carried out indirectly, in particular with one, two or more additional layers, or also directly on the photoactive layer, direct covering being preferred. The covering of the photoactive layer with the composition in process step II) can be carried out by all the processes known to the person skilled in the art by means of which a substrate can be covered with liquid compositions in a particular wet film thickness. Preferably, the application of the composition to the photoactive layer is carried out by spin coating, impregnation, pouring, dripping on, spraying, misting, knife coating, brushing or printing, for example ink-jet, screen, gravure, offset or tampon printing, in a wet film thickness of from 0.5 μm to 250 μm, preferably in a wet film thickness of from 1 μm to 50 μm. Preferably, the concentration of the electrically conductive polymer in the liquid composition is in a range of from 0.01 to 7 wt. %, preferably in a range of from 0.1 to 5 wt. % and particularly preferably in a range of from 0.2 to 3 wt. %, in each case based on the liquid composition.

One embodiment of the additional layer is formed from a hole conductor material. Hole conductor materials in so-called “solid state dye sensitized solar cells” (ssDSSCs) are preferred. These are preferably formed from solution or by a melt flow infiltration process. In particular, this applies to spiro compounds, in particular (2,2′,7,7′-tetrakis(N,N-di-p-methoxyphenylamine)-9,9′-spirobifluorene (spiro-OMeTAD) (cf. Leijtens et al. ACS Nano, 2012, 6, 2, 1455-1462), which is preferably soluble in a halogenated, preferably aromatic solvent, such as dichlorobenzene, preferably in a range of from 10 to 50 wt. %, based on the solution.

It is furthermore preferable according to the invention for the composition to remain in contact with the surface of the photoactive layer under defined conditions after application of the composition to the photoactive layer, before process step III) is carried out. In this connection it is particularly preferable for the composition to remain in contact with the surface of the photoactive layer at a temperature in a range of from 4 to 75° C., particularly preferably in a range of from 15 to 25° C. and for a duration in a range of from 0 to 10 minutes, particularly preferably in a range of from 1 to 6 minutes, in order to ensure an adequate superficial dissolving of the photoactive layer. When choosing suitable temperatures, it is preferable for the solvent employed to be liquid during the covering.

In process step III) of the process according to the invention, the organic solvent b) is then at least partially, but preferably as completely as possible, removed from the composition used for covering in process step II) to obtain a conductive layer covering the photoactive layer, this removal preferably being carried out by drying at a temperature in a range of from 20° C. to 220° C., preferably 100-150° C. It may be advantageous in this context for the supernatant composition to be at least partially removed from the substrate, for example by spinning off, before the drying process.

The thickness of the conductive layer used for covering the photoactive layer in this manner is preferably in a range of from 10 to 500 nm, particularly preferably in a range of from 20 to 80 nm. The above layer thicknesses relate to the layers after the drying.

A contribution towards achieving at least one of the abovementioned objects is also made by a layered body obtainable by the process according to the invention.

Due to the effect described above, according to which a brief, slight superficial dissolving of the underlying photoactive layer by the adhesion promoter additive d) takes place and as a consequence of which during the application of the composition comprising the conductive polymer a partial mixing of the components at the interface is rendered possible, the layered bodies obtainable by the process according to the invention are distinguished by a completely novel structure compared with the comparable layered bodies known from the prior art. Preferably, the layered bodies obtainable by the process according to the invention comprise
i) the photoactive layer comprising at least one hydrophobic compound;
ii) the conductive layer which comprises a conductive polymer and covers the photoactive layer; and
iii) an intermediate layer which is located between the photoactive layer and the conductive layer and comprises a mixture of the conductive polymer from the conductive layer and the at least one hydrophobic compound from the photoactive layer.

In this connection it is particularly preferable for the photoactive layer to comprise less conductive polymer from the conductive layer than the intermediate layer and for the conductive layer to comprise less of the at least one hydrophobic compound from the photoactive layer than the intermediate layer. Very particularly preferably,
the region of the first 10 nm of the photoactive layer on the side facing away from the conductive layer is based to the extent of at least 90 wt. %, particularly preferably to the extent of at least 95 wt. % and most preferably to the extent of about 100 wt. % on the at least one hydrophobic compound, but particularly preferably on P3HT:PCBM;
the region of the first 10 nm of the conductive layer on the side facing away from the photoactive layer is based to the extent of at least 90 wt. %, particularly preferably to the extent of at least 95 wt. % and most preferably to the extent of about 100 wt. % on the conductive polymer, but particularly preferably on PEDOT:PSS; and
the intermediate layer comprises an at least 1 nm wide region in which the weight ratio of hydrophobic compounds from the photoactive layer: conductive polymer from the conductive layer, but particularly preferably the weight ratio of the total amount of P3HT and PCBM to the total amount of PEDOT and PSS, is in a range of from 10:1 to 1:10, particularly preferably in a range of from 5:1 to 1:5. As a rule, the thickness of the intermediate layer is below the total thickness of all the layers of the layered body. A layer thickness of the intermediate layer of down to 10 nm or even 5 nm is often observed.

Furthermore, the layered body obtainable by the process according to the invention is preferably characterized in that the removed area of the conductive layer in the “cross-cut tape” test described herein is less than 5%, particularly preferably less than 2.5% and most preferably less than 1%.

A contribution towards achieving at least one of the abovementioned objects is also made by a layered body comprising
i) a photoactive layer comprising at least one hydrophobic compound;
ii) a conductive layer which comprises a conductive polymer and covers the photoactive layer; and
iii) an intermediate layer which is located between the photoactive layer and the conductive layer and comprises a mixture of the conductive polymer from the conductive layer and the at least one hydrophobic compound from the photoactive layer.

Those hydrophobic compounds and conductive polymers which have already been mentioned above as preferred hydrophobic compounds and conductive polymers in connection with the process according to the invention are preferred as the hydrophobic organic compound and as the conductive polymer in this context. The layered body according to the invention furthermore has the same properties as the layered body obtainable by the process according to the invention with respect to its structure and its properties, in particular with respect to it properties in the “cross-cut” test.

A contribution towards achieving at least one of the abovementioned objects is also made by an organic photovoltaic cell (solar cell) comprising a layered body obtainable by the process according to the invention or a layered body according to the invention. In this context, as the organic photovoltaic cell are used in particular those solar cells, in the production of which a conductive layer comprising a conductive polymer, in particular a PEDOT:PSS layer, is superimposed on a photoactive layer comprising at least one hydrophobic compound, in particular a photoactive P3HT:PCBM layer, and in particular is superimposed.

An organic photovoltaic cell conventionally comprises two to five layers, conventionally superimposing a substrate, which result in a layer sequence which in turn can recur two and more times, for example in a tandem cell. A layer sequence conventionally comprises a hole contact or hole-collecting layer (often called the anode), a hole transport layer (as a rule a p-type semiconductor or PEDOT having metallic electrical conductivity), a photoactive layer (comprising electron acceptor material and electron donor material), optionally an electron transport layer (as a rule an n-type semiconductor) and an electron contact or electron collecting electrode (often called the cathode), the anode and/or the cathode being light-transmitting (i.e. transparent or—alternatively—designed in the form of a light-transmitting strip grid, or highly conductive PEDOT). Depending on the sequence of the hole transport layer and electron transport layer with respect to the substrate, in this context a distinction is made between an organic photovoltaic cell of “regular structure” (hole contact is the electrode close to the substrate) and an organic photovoltaic cell of “inverted structure” (hole contact is the electrode remote from the substrate).

The substrate which the layered structure described above is superimposed on preferably a material which is substantially transparent (colourless and transparent, coloured and transparent, or clear and transparent), in particular in the wavelength range of the absorption spectra of the active materials (electron donor and acceptor materials), and renders possible the passage of external light, such as, for example, sunlight. Examples of the substrate include glass substrates and polymer substrates. Non-limiting examples of polymers for the substrate include polyether sulphone (PES), polyacrylate (PAR), polyether-imide (PEI), polyethylene naphthalate (PEN), polyethylene terephthalate (PET), polyphenylene sulphide (PPS), polyallylate, polyimide, polycarbonate (PC), cellulose triacetate (TAC) and cellulose acetate propionate (CAP). When choosing suitable substrates it is preferable for these to be suitable for a reel-to-reel production process for the layered body. The substrate can furthermore be equipped with additional functional coatings. Antireflection finishes, antireflective agents, UV blockers and gas and moisture barriers are preferred here. The substrate can have a single-layer structure which comprises a mixture of at least one material. In another embodiment, it can have a multilayer structure, which comprises layers arranged one above the other, each of which comprises at east two types of materials.

Possible materials for the anode layer and the cathode layer are all the components which, to the person skilled in the art, can conventionally be employed for the production of conductive layers in solar cells, the choice being determined, inter alia, by whether or not the anode or cathode layer must be light-transmitting. Preferred examples for the material of the anode and cathode layer include transparent and highly conductive materials, such as, for example, indium tin oxide (ITO), indium zinc oxide (IZO), tin oxide (SnO₂), zinc oxide (ZnO), fluorotin oxide (FTO) and antimony tin oxide (ATO). Further examples of the material of the anode or cathode layer include ultra-thin and thin metal layers of magnesium (Mg), aluminium (Al), platinum (Pt), silver (Ag), gold (Au), copper (Cu), molybdenum (Mo), titanium (Ti), tantalum (Ta), a combination of at least two of these (e.g. an alloy of these, aluminium-lithium, calcium (Ca), magnesium-indium (Mg—In) or magnesium-silver (Mg—Ag), which can be present in a co-deposition layer) and carbon-containing materials, such as, for example, graphite and carbon nanotubes. In this context, the metal layers described above, if they are to be light-transmitting, can be either ultra-thin or also in the form of a strip grid or used for covering as nanotubes, nanowires or networks thereof. Conductive layers comprising conductive materials, for example conductive PEDOT:PSS layers, are furthermore also possible above all as transparent materials for the anode or cathode layer. The thickness of the anode and cathode layer is conventionally in a range of from 2 to 500 nm, particularly preferably in a range of from 50 to 200 nm. Ultra-thin transparent or semitransparent metal layers are particularly preferred and have a thickness in a range of from 2 to 20 nm.

Possible materials for the electron transport layer are, in particular, n-type semiconducting metal oxides, such as, for example, zinc oxide, tin dioxide, titanium dioxide and suboxide (TiOₓ), tin(IV) oxide, tantalum(V) oxide, caesium oxide, caesium carbonate, strontium titanate, zinc stannate, a complex oxide of the Perowskit-type, in particular barium titanate, a binary iron oxide or a ternary iron oxide, caesium carbonate, zinc oxide or titanium dioxide being particularly preferred. The thickness of the electron transport layer is conventionally in a range of from 2 nm to 500 nm, particularly preferably in a range of from 10 to 200 nm.

The organic photovoltaic cell according to the invention is thus preferably characterized in that a conductive layer comprising a conductive polymer is employed as the hole transport layer, and in that the layered body obtainable by the process according to the invention or the layered body according to the invention is integrated into the organic photovoltaic cell such that the photoactive layer corresponds to the photoactive layer and the conductive layer comprising the conductive polymer corresponds to the hole transport layer. In the production of the organic photovoltaic cell according to the invention, during the application of the hole transport layer to the photoactive layer, preferably during the application of a PEDOT:PSS layer as the hole transport layer to a P3HT:PCBM layer as the photoactive layer, the process according to the invention described above for the production of a layered body is preferably employed.

According to one embodiment, the organic photovoltaic cell (5) according to the invention according to claim 25 comprises

a. an anode;
b. the layered body as defined in this document;
c. where appropriate an electron transport layer; and
d. a cathode.

According to a first preferred embodiment of the organic photovoltaic cell, this cell is a cell having an “inverted structure” comprising
(α1) a transparent cathode, for example a layer of silver, aluminium or ITO in a thickness in a range of from 5 to 150 nm, superimposed on a transparent substrate;
(α2) an electron transport layer following the cathode (α1), for example a titanium oxide or zinc oxide layer in a thickness in a range of from 10 to 200 nm;
(α3) a photoactive layer following the electron transport layer (α3), for example a P3HT:PCBM layer in a thickness in a range of from 50 to 350 nm;
(α4) a hole transport layer following the photoactive layer (α3), preferably a PEDOT:PSS layer having a thickness in a range of from 20 to 250 nm;
(α5) an anode following the hole transport layer (α4), for example a silver layer having a thickness in a range of from 20 to 200 nm;
   wherein the photoactive layer (α3) corresponds to the photoactive layer and the hole transport layer (α4) corresponds to the conductive layer superimposed on the photoactive layer. In such an organic photovoltaic cell, light is incident from below (that is to say through the transparent cathode). In (α4) the thickness can be up to 1,000 nm if the PEDOT:PSS layer is used as an electrode.

According to a second preferred embodiment of the organic photovoltaic cell, this cell is a cell having an “inverted structure” comprising
(β1) an anode superimposed on a substrate, for example an aluminium layer having a thickness in a range of from 5 to 150 nm, which can optionally be superimposed on by a titanium oxide or zinc oxide layer in a thickness in a range of from 5 to 200 nm (as the electron transport layer);
(β2) a photoactive layer following the anode (β1), for example a P3HT:PCBM layer in a thickness in a range of from 50 to 350 nm;
(β3) a hole transport layer following the photoactive layer (β2), preferably a PEDOT:PSS layer having a thickness in a range of from 20 to 250 nm;
(β4) a cathode following the hole transport layer (β3), preferably a layer of a metal in the form of a strip grid of gold, aluminium, silver or copper or at least two of these;
   wherein the photoactive layer (β2) corresponds to the photoactive layer and the hole transport layer (β3) corresponds to the electrically conductive layer superimposed on the photoactive layer. In such an organic photovoltaic cell, light is incident from above (that is to say through the anode in the form of a strip grid).

A contribution towards achieving at least one of the abovementioned objects is also made by a solar cell module, comprising at least one, preferably at least two of the photovoltaic cells according to the invention.

A contribution towards achieving at least one of the abovementioned objects is also made by a composition, preferably a dispersion, comprising, based on the total weight of the composition,
0.1 to 5 wt. %, particularly preferably 0.4 to 3 wt. % and most preferably 0.5 to 0.7 wt. % of PEDOT:PSS;
50 to <100 wt. %, particularly preferably 68 to 99 wt. % and most preferably 78 to 96 wt. % of an organic solvent chosen from the group consisting of ethylene glycol, propanediol, ethanol and mixtures of at least two of these;
0.1 to 1.1 wt. %, particularly preferably 0.1 to 0.5 wt. % and most preferably 0.2 to 0.4 wt. % of a surfactant, particularly preferably a surfactant, preferably a “gemini surfactant”, based on siloxanes;
1 to 15 wt. %, particularly preferably 2.5 to 12.5 wt. % and most preferably 5 to 10 wt. % of an adhesion promoter additive chosen from the group consisting of xylene, toluene, THF, styrene, anisole, cyclohexane, chlorobenzene, dichlorobenzene or mixtures of at least two of these, particularly preferably dichlorobenzene;
0 to 15 wt. %, particularly preferably 0.5 to 10 wt. % and most preferably 5 to 10 wt. % of one or more auxiliary substances, such as, for example, one or more auxiliary solvents, particularly preferably iso-propanol as an auxiliary solvent.

Preferred surfactants and auxiliary substances in this context are those surfactants and auxiliary substances which have already been mentioned above as preferred surfactants and auxiliary substances in connection with the process according to the invention for the production of a layered body.

It is furthermore preferable according to the invention for the composition according to the invention to have at least one, but preferably all of the following properties:
A) the composition comprises, based on the total weight of the composition, less than 6 wt. %, particularly preferably less than 4 wt. % and most preferably less than 2 wt. % of water;
B) the weight ratio of PEDOT:PSS in the composition is in a range of from 1:0.5 to 1:25, particularly preferably in a range of from 1:2 to 1:20 and most preferably in a range of from 1:2 to 1:6;
C) a conductive film formed from the composition is characterized by a specific resistance of less than 10,000 Ω·cm, particularly preferably less than 10 Ω·cm and most preferably of less than 1 Ω·cm.

Particularly advantageous compositions according to the invention are characterized by the following properties or following combinations of properties: A), B), C), A)B), A)C), B)C) and A)B)C), wherein the combination of properties A)B)C) is most preferred.

The use of an ideally water-free dispersion comprising PEDOT:PSS renders possible a complete elimination of water in a production process, which is very important precisely in applications in the electronics field. It thus also renders possible the processing of the dispersion under an inert protective atmosphere, such as a glove box, in which the influence of moisture is to be avoided at all cost. This makes the dispersion compatible in terms of the production process with all processes which are carried out with exclusion moisture. For OPV cells, contact with the sensitive active layer is thus completely avoided, which can have a positive effect on the long-term stability.

A contribution towards achieving at least one of the abovementioned objects is also made by the use of the composition according to the invention (or of the composition described in connection with the process according to the invention) for the production of a conductive layer on a P3HT:PCBM layer or improving the adhesion of the conductive layer on a P3HT:PCBM layer. With respect to preferred embodiments of the conductive layer, reference is made to the above statements.

The invention is now explained in more detail with the aid of figures, test methods and non-limiting examples.

FIG. 1 shows a diagram of the layer sequence through a layered body 1 according to the invention or through a layered body 1 obtainable by the process according to the invention. The layered body 1 comprises a photoactive layer 3, which is preferably a layer comprising P3HT:PCBM as hydrophobic compounds. A conductive layer 2 comprising a conductive polymer, which is preferably a PEDOT:PSS layer, is applied to the photoactive layer 3. Between the photoactive layer 3 and the conductive layer 2 there is located an intermediate layer 4 which comprises a mixture of the conductive polymer from the conductive layer 2 and the at least one hydrophobic compound from the photoactive layer 3.

FIG. 2 shows a diagram of the layer sequence through a first particularly preferred organic photovoltaic cell, comprising a layered body 1 according to the invention or a layered body 1 obtainable by the process according to the invention. This cell comprises a substrate 9 (preferably of glass), on to which is applied an approximately 100 nm thick transparent cathode layer 8 of e.g. an aluminium or silver grid or ITO. The cathode layer 8 is followed by an electron transport layer 7, such as e.g. a titanium oxide or a zinc oxide layer in a thickness of from 5 nm to 200 nm. On this is found the photoactive layer 3′, which is preferably a P3HT:PCBM layer having a thickness of from about 80 to 250 nm. On to this photoactive layer is then applied, by means of the process according to the invention, a hole transport layer 2′ forming an intermediate layer 4′ which comprises a mixture of the components of layers 2′ and 3′. Finally, the hole transport layer 2′ is followed by an anode layer 6, which can be, for example, a silver layer. In this embodiment of an organic photovoltaic cell, light is incident, as shown in FIG. 2, from underneath through the substrate layer 9.

FIG. 3a shows a diagram of the layer sequence through a second particularly preferred organic photovoltaic cell, comprising a layered body 1 according to the invention or a layered body 1 obtainable by the process according to the invention. This cell likewise comprises a substrate 9 (preferably of glass), on to which is applied an approximately 100 nm thick cathode layer 8 of e.g. aluminium. The cathode layer 8 can be followed by a layer 7 having a thickness in a range of from 10 to 50 nm. On this is found the photoactive layer 3′, which is preferably a P3HT:PCBM layer having a thickness of from about 80 to 250 nm. On to this photoactive layer 3′ is then applied again, by means of the process according to the invention, a hole transport layer 2′ forming an intermediate layer 4′ which comprises a mixture of the components of layers 2′ and 3′. Finally, the hole transport layer 2′ is followed by an anode layer 6 in the form of a metallic strip grid, for example of gold or copper. In this embodiment of an organic photovoltaic cell, light is incident, as shown in FIG. 3, from above through the PEDOT:PSS layer.

FIG. 3b shows, in addition to the embodiments for FIG. 3a, that both the electrode-collecting layer 8 and the substrate 9 are configured as light-transmitting. The photovoltaic cell can thus, from both sides, convert incident light impinging on these into electrical energy.

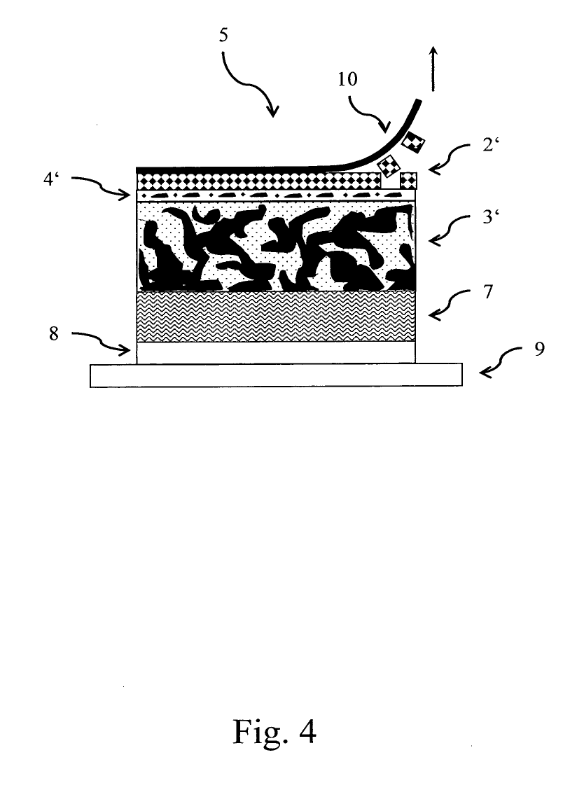

FIG. 4 shows the manner in which the “cross-cut tape” test is carried out for determination of the strength of the adhesion with which the conductive layer (2) comprising the conductive polymer, preferably the PEDOT:PSS layer, adheres to the photoactive layer, preferably to the P3HT:PCBM layer. In this context, an adhesive strip (“tape”) 10 is stuck on to the conductive layer 2′ and then peeled off in the direction of the straight arrow shown in FIG. 4.

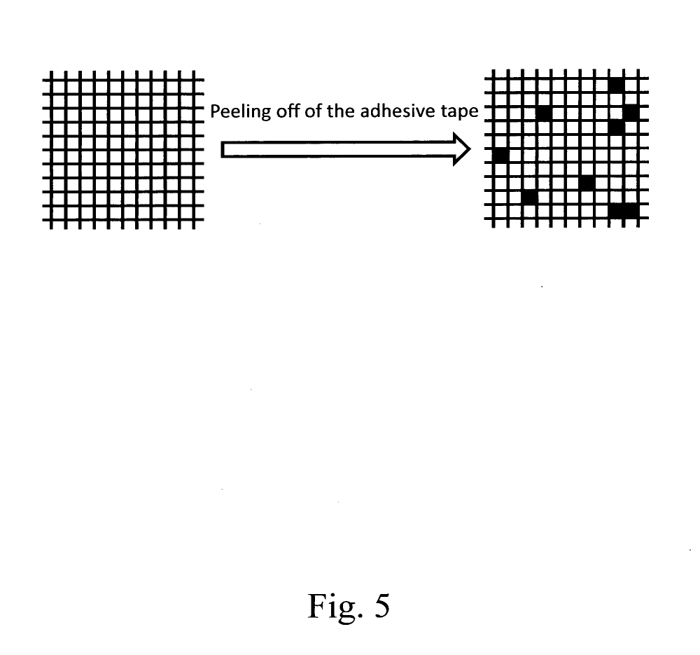

FIG. 5 shows how the result of the “cross-cut tape” test shown in FIG. 4 is evaluated analytically.

### Test Methods

To evaluate the adhesion of a layer of the composition employed in the process according to the invention to the photoactive layer, the procedure is as follows:

### Substrate Cleaning

ITO-precoated glass substrates (5 cm×5 cm) are cleaned by the following process before use: 1. thorough rinsing with acetone, isopropanol and water, 2. ultrasound treatment in a bath at 70° C. in a 0.3% strength Mucasol solution for 15 min, 3. thorough rinsing with water, 4. drying by spinning off in a centrifuge, 5. UV/ozone treatment (PR-100, UVP Inc., Cambridge, GB) for 15 min directly before use.

### ZnO Layer

In each case solutions of 0.75 M zinc acetate (164 mg/ml) in 2-methoxyethanol and 0.75 M monoethanolamine (45.8 mg/ml) in 2-methoxyethanol are first prepared separately in two glass beakers and stirred at room temperature for 1 h. Thereafter, the two solutions were mixed in the volume ratio of 1:1, while stirring, and the mixture is stirred until a homogeneous, clear Zn precursor solution is formed. Before use, this is also filtered over a syringe filter (0.45 μm, Sartorius Stedim Minisart). This is then applied to the cleaned ITO substrate by spin coating at 2,000 rpm for 30 s and then dried in air on a hot-plate at 130° C. for 15 min.

### Active Layer

The photoactive layer (e.g. a photoactive P3HT:PCBM layer) is applied to the abovementioned ZnO-coated ITO substrate by spin coating and dried, so that a homogeneous, smooth film is formed. In the case of P3HT:PCBM, a solution with 1.5 wt. % of P3HT (BASF, Sepiolid P200) and 1.5 wt. % of PCBM (Solenne, 99.5% purity) in the ratio of 1:1 (total of 3 wt. %) in 1,2-dichlorobenzene is first prepared in a screw cap pill bottle and stirred at 60° C. under a nitrogen atmosphere for at least 4 h or until all the material has dissolved. Thereafter, the solution is cooled to room temperature, while stirring, and filtered with a syringe filter (0.45 μm, Sartorius Minisart SRP 25). The entire process of application of the active layer takes place under a nitrogen atmosphere in a glove box. The P3HT:PCBM solution is now dripped on to the ITO/ZnO substrate and superfluous solution is spun off by spin coating at 450 rpm for 50 s. The layers are then dried directly on a hot-plate at 130° C. for 15 min.

### Conductive Layer: PEDOT:PSS Layer

For the production of the PEDOT:PSS layer, the dispersion according to the invention, the coating composition, is dripped on to the abovementioned photoactive layer (layer sequence glass substrate/ITO/ZnO/P3HT:PCBM as a precursor (cf. sample preparation)). The coating composition (either I, II and III) was applied to the P3HT:PCBM layer of the precursor by means of a pipette to completely cover the area. After an action time of 3 min, the coating composition which had not penetrated into the precursor was spun off by spin coating (conditions: 30 s at approx. 1,000 rpm). Thereafter, a drying process on a hot-plate was carried out in three steps: 1 min at room temperature, followed by 15 min at 130° C. For the test on the aqueous comparative examples a) and b) in the same layer sequence of glass substrate/ITO/ZnO/P3HT:PCBM as the precursor, the PEDOT:PSS layer was in turn formed on the P3HT:PCBM layer. The aqueous PEDOT:PSS type was applied to the P3HT:PCBM layer of the precursor by means of a pipette to completely cover the area and was immediately spun off by spin coating (conditions: 30 s at approx. 1,500 rpm). Thereafter, a drying process on a hot-plate was carried out with 15 min at 130° C.

### OPV Cells

For the further test of the coating composition according to the invention in use, OPV cell having the following inverted layer structure of glass substrate/ITO/ZnO/P3HT:PCBM/conductive PEDOT:PSS layer/silver were produced, ZnO having been applied with a layer thickness of approx. 50 nm, P3HT:PCBM with a layer thickness of approx. 170 nm and PEDOT:PSS of about 50 nm, in the given sequence in accordance with the instructions already described above. In this context, two PEDOT:PSS dispersions were tested: the organic coating composition Ia according to the invention with adhesion promoter additive in cell Ia and the aqueous comparative example b) in cell b). The silver electrodes having a layer thickness of 300 nm were vapour-deposited using a reduced pressure vapour deposition unit (Edwards) at <5*10⁻⁶ mbar through shadow masks with a vapour deposition rate of about 10 Å/s. The shadow masks define the photoactive area of 0.049 cm³. For accurate photocurrent measurement, the individual cells were carefully scratched out with a scalpel and therefore reduced to the precisely defined area, in order to avoid edge effects with additionally collected current due to highly conductive PEDOT:PSS.

### Wettability

It is first tested whether the dispersion adequately wets the active layer at all. The contact angle which the dripped-on solution forms with the surface is used as a criterion for good wetting. The contact angle is measured with a Krüss (Easy Drop) in that a stationary drop is deposited on the horizontally lying substrate.

### Superficial Dissolving Properties

The superficial dissolving of the photoactive layer is checked in that a stationary film of liquid which covers the photoactive layer in each case is washed off with isopropanol after 3 and 10 min and the layer is then dried. The film of liquid was applied over a large area on the active layer with a pipette. If superficial dissolving takes place during the covering, this leads to a visible change in the colour or intensity of the contact area of the film. The superficial dissolving effect by the composition which, in addition to the conductive polymer, in particular comprises the adhesion promoter additive was measured by UV/Vis spectroscopy (PerkinElmer Lambda 900). In this context, the absorption of the non-treated active layer was measured and compared at exactly the same place before application of the liquid film and after washing off and drying. For the comparison, two characteristic wavelengths of the absorption spectrum of the active material at which a change is easily visible were chosen: 510 nm for P3HT and 400 nm for PCBM. The change in the absorption in a wavelength then expresses the reduction in absorption and the associated detachment of material. If the liquid film does not lead to any superficial dissolving the surface remains unchanged, if dissolving is complete the film is missing at the contact area.

### Adhesion Measurement

The adhesion can be determined semi-quantitatively in a standard tape test method, the so-called “cross-cut tape” test (Test Method B from ASTM D 3359-08), in accordance with a specified classification scale (see ASTM D 3359-08, FIG. 1, page 4). In this, a grid of 10 times 10 squares of 1 mm×1 mm (see FIG. 5) is cut into the layers and peeled off with an adhesive tape (Post-it, 3M) in the way as in the first “tape” test. After the area of squares removed has been counted, the adhesion can be classified (area of layer removed: 0%=5B, <5%=4B, 5-15%=3B, 15-35%=2B, 35-65%=1B, >65%=0B).

### Cell Characterization

The OPV cells produced were measured with a solar simulator (1,000 W quartz-halogen-tungsten lamp, Atlas Solar Celltest 575) with a spectrum of 1.5 AM. The light intensity can be attenuated with inserted grating filters. The intensity at the sample plane is measured with an Si photocell and is approx. 1,000 W/m². The Si photocell was calibrated beforehand with a pyranometer (CM10). The temperature of the sample holder is determined with a heat sensor (PT100+testtherm 9010) and is max. 40° C. during the measurement. The two contacts of the OPV cell are connected to a current/voltage source (Keithley 2800) via a cable. For the measurement, the cell was scanned in the voltage range of from −1.0 V to 1.0 V and back to −1.0 V in steps of 0.01 V and the photocurrent was measured. The measurement was performed three times per cell in total, first in the dark, then under illumination and finally in the dark again, in order to guarantee complete functioning of the cell after illumination. A substrate has nine cells, the average of which is taken. The data were recorded via a computer-based Labview program. This leads to the typical current density/voltage characteristic line of a diode, from which the OPV characteristic data, such as “open circuit voltage” (V_{oc}), “short circuit current density” (J_{sc}), fill factor (FF) and efficiency or effectiveness (Eff.) can be determined either directly or by calculation in accordance with the European standard EN 60904-3. The fill factor is then calculated according to Equation 1:

$$FF = \frac{{V}_{mpp} {J}_{mpp}}{{V}_{OC} {J}_{SC}} \qquad Equation 1$$

wherein Vₘₚₚ is the voltage and Jₘₚₚ the current density at the “maximum power point” (mmp) on the characteristic line of the cell under illumination.

### Electrical Conductivity:

The electrical conductivity means the inverse of the specific resistance. The specific resistance is calculated from the product of surface resistance and layer thickness of the conductive polymer layer. The surface resistance is determined for conductive polymers in accordance with DIN EN ISO 3915. In concrete terms, the polymer to be investigated is applied as a homogeneous film by means of a spin coater to a glass substrate 50 mm×50 mm in size thoroughly cleaned by the abovementioned substrate cleaning process. In this procedure, the coating composition is applied to the substrate by means of a pipette to completely cover the area and spun off directly by spin coating. The spin conditions for coating compositions I, II and III are 1,000 rpm for 30 s, and for comparative examples a) and b) 1,500 rpm for 30 s. Thereafter, a drying process on a hot-plate of 15 min at 130° C. was carried out. Ag electrodes of 2.0 cm length at a distance of 2.0 cm are vapour-deposited on to the polymer layer via a shadow mask. The square region of the layer between the electrodes is then separated electrically from the remainder of the layer by scratching two lines with a scalpel. The surface resistance is measured between the Ag electrodes with the aid of an ohmmeter (Keithley 614). The thickness of the polymer layer is determined with the aid of a Stylus Profilometer (Dektac 150, Veeco) at the places scratched away.

### Examples

### Process for Producing a Stock Dispersion

### a) Stock Dispersion a:

A non-aqueous PEDOT:PSS dispersion (stock dispersion) based on the PEDOT:PSS screen printing paste Clevios™ S V3 was prepared. The stock dispersion contains PEDOT Clevios S V3 (37.7 wt. %), diethylene glycol (5.2 wt. %), propanediol (27.0 wt. %), Disparlon (0.1 wt. %), ethanol (30.0 wt. %). For a batch of the stock dispersion, 241.7 g of PEDOT Clevios S V3 were first dispersed for one hour at 1,500 rpm using a Dispermat CV/S from VMA-Getzmann GmbH. 33.64 g of diethylene glycol, 173.17 g of 1,2-propanediol and 0.58 g of Disparlon were then added in the stated sequence, while stirring, and dispersing was carried out for 4 hours at 1,000 rpm using a Dispermat CV/S from VMA-Getzmann GmbH. The dispersion was then filtered twice over a filter of the Seitz 3500 type. A further 156.91 g of ethanol were then added to this batch and the mixture was stirred with a magnetic stirrer at 200-300 rpm for 15 min. The finished stock dispersion had a residual content of 5.9 wt. % of water and a solids content of 0.7 wt. %. The water content was determined by Karl-Fischer titration.
Before use, the stock dispersion was filtered over a 5 μm syringe filter (Minisart, Sartorius) at room temperature.

### b) Stock Dispersion b:

The stock dispersion obtained in a) can be significantly improved in several important parameters, such as viscosity, opacity/turbidity of the layer and filterability, by post-processing. The process starting with the stock dispersion and resulting in a post-processed stock dispersion comprises the following steps: filtration through a depth filter followed by ultrasound treatment.
For post processing 2000 g of the stock dispersion obtained in a) was filtered once through a filter of the type Seitz 3500. The thus obtained stock dispersion was then treated with an ultrasonic cell of the type Sartorius Labsonic® P. For that purpose 2 liters per minute of the dispersion were pumped in an open circuit under ice cooling through the ultrasonic cell. The mixture was treated in this way for about 4 hours or until a viscosity of less than 30 mPas was reached. The thus obtained final post-processed stock dispersion had a reduced viscosity of 25-30 mPas (compared to the stock dispersion obtained in a) and having a dispersion of 50 mPas; see table 1).

The viscosity was measured with a Roto Visco 1 obtained by Thermo Scientific at a shear rate of 100/s. Furthermore, the turbidity (haze) was measured of thin, dry, 120-nm-thick layers of the post-processed stock dispersion on glass (prepared as for conductivity measurements).
Surprisingly, the turbidity has been reduced by the post-processing from 6 (relatively opaque) to 0.3 (clear). The turbidity was measured using a Haze-Gard Plus obtained from Byk. For determining the turbidity (haze), the total transmittance was measured (for the luminant C) according to ASTM D 1003. The value is the percentage of transmitted light which deviates from the incident light beam in the average by more than 2.5°. The conductivity of the stock dispersion is not significantly changed by the post-processing and remains constantly high at 100-150 S/cm. The filterability of the post-processed stock dispersion through a 5 μm syringe filter was drastically improved by the post-processing from initially about 3.5 ml to more than 100 ml and thus enables a scaling up the processing of the material. Filterability through a 5 μm syringe filter was measured by determining the volume of the filtrate with moderate finger pressure through the syringe filter.

TABLE 1
Comparison of the properties of the stock dispersion obtained
in a) and the post-processed stock dispersion obtained in b):

| | stock dispersion | stock dispersion |
|---|---|---|
| parameter | obtained in a) | obtained in b) |
| viscosity [mPas] | 50 | 25-30 |
| turbidity [%] | 6 | 0.3 |
| (layer thickness ~120 nm) | | |
| conductivity [S/cm] | 100-150 | 100-150 |
| filterability through 5 μm | 3.5 | >100 |
| syringe filter [ml] | | |

A composition according to the invention was prepared according to the following recipe:

PEDOT:PSS in Organic Solvent with Surfactant and Adhesion Promoter Additive (Composition I According to the Invention):

### Composition Ia:

The percentage by weight stated in the batch relates to the size of the total batch of composition Ia of 5.00 g, which corresponds to 100 wt. %. The batch of composition Ia therefore comprises 5 wt. % of adhesion promoter additive.
4.47 g [89.4 wt. %] of the stock dispersion obtained in a)
0.03 g [0.6 wt. %] of surfactant solution (containing 0.015 g [0.3 wt. %] of surfactant TEGO™ TWIN 4000 as a siloxane (Evonik) and 0.015 g [0.3 wt. %] of iso-propanol as the first auxiliary solvent)
0.50 g [10.0 wt. %] of adhesion promoter additive solution (containing 0.25 g [5 wt. %] of dichlorobenzene and 0.25 g [5 wt. %] of iso-propanol as the second auxiliary solvent)

### Composition Ib:

The percentage by weight stated in the batch relates to the size of the total batch of composition Ib of 5.00 g, which corresponds to 100 wt. %. The batch of composition Ib therefore comprises 15 wt. % of adhesion promoter additive.
3.47 g [69.4 wt. %] of the stock dispersion obtained in a)
0.03 g [0.6 wt. %] of surfactant solution (containing 0.015 g [0.3 wt. %] of surfactant TEGO™ TWIN 4000 as a siloxane (Evonik) and 0.015 g [0.3 wt. %] of iso-propanol as the first auxiliary solvent)
1.5 g [30.0 wt. %] of adhesion promoter additive solution (containing 0.75 g [15 wt. %] of dichlorobenzene and 0.75 g [15 wt. %] of iso-propanol as the second auxiliary solvent)

The stock dispersion was provided. The surfactant solution and the additive solution were then added in this sequence, with constant stirring. The mixture was then stirred until a homogeneous intimate mixture of the dispersion and the components was present as the coating composition. The conductivity of coating compositions Ia and Ib was 100-150 S/cm.

PEDOT:PSS in Organic Solvent with Surfactant (Composition II According to the Invention):

The percentage by weight stated in the batch relates to the size of the total batch of composition II of 5.00 g, which corresponds to 100 wt. %.
4.97 g [99.4 wt. %] of the stock dispersion obtained in a)
0.03 g [0.6 wt. %] of surfactant solution (containing 0.015 g [0.3 wt. %] of surfactant TEGO™ TWIN 4000 as a siloxane (Evonik) and 0.015 g [0.3 wt. %] of iso-propanol as the first auxiliary solvent)

The stock dispersion was provided. The surfactant solution was then added, with constant stirring. The mixture was then stirred until a homogeneous intimate mixture of the dispersion and the components was present as the coating composition. The conductivity of coating composition II was 100-150 S/cm.

### PEDOT:PSS in Organic Solvent (Composition III According to the Invention):

The percentage by weight stated in the batch relates to the size of the total batch of composition III of 5.00 g, which corresponds to 100 wt. %.
5.00 g [100 wt. %] of the stock dispersion obtained in a)

The conductivity of coating composition III was 100-150 S/cm.

### Comparative Examples with a) Water; b) Water and Surfactant

For a comparison, the non-aqueous PEDOT:PSS types (composition Ia and Ib, II and III) were compared with the aqueous PEDOT:PSS types (comparative example a) and b)). An aqueous PEDOT:PSS dispersion (comparison stock dispersion) based on the PEDOT:PSS Clevios™ PH510 without high-boiling substance (dimethylsulphoxide) was prepared. The comparison stock dispersion is based on PEDOT Clevios™ PH510.

For a batch of the comparison stock dispersion, 10.0 g of PEDOT Clevios™ PH510 were initially introduced into a glass beaker and 8.0 g of water were added, while stirring. The mixture was then stirred with a magnetic stirrer at 200 rpm until a homogeneous intimate mixture of the dispersion was present. The comparison stock dispersion had a solids content of 1.0 wt. %.

### Comparative Example a)

The percentage by weight stated in the batch relates to the size of the total batch of the composition of comparative example a) of 5.00 g, which corresponds to 100 wt. %.
5.00 g [100 wt. %] of the above comparison stock dispersion

The aqueous PEDOT:PSS dispersion without surfactant is used directly and in unchanged form. The conductivity of comparative example 1a) was 0.1-1 S/cm. Before use, the dispersion was filtered over a hydrophilic 0.45 μm syringe filter (Sartorius Stedim Minisart) at room temperature.

### Comparative Example b)

The percentage by weight stated in the batch relates to the size of the total batch of the composition of comparative example b) of 5.00 g, which corresponds to 100 wt. %.
4.97 g [99.4 wt. %] of the above comparison stock dispersion
0.03 g [0.6 wt. %] of surfactant solution (containing 0.015 g [0.3 wt. %] of surfactant TEGO™ TWIN 4000 as a siloxane (Evonik) and 0.015 g [0.3 wt. %] of iso-propanol as the first auxiliary solvent)

The comparison stock dispersion was provided. The surfactant solution was then added, with constant stirring. The mixture was then stirred until a homogeneous intimate mixture of the dispersion and the components was present as the coating composition. The conductivity of comparative example 1a) was 0.1-1 S/cm. Before use, the dispersion was filtered over a hydrophilic 0.45 μm syringe filter (Sartorius Stedim Minisart) at room temperature.

TABLE 2
(parts 1 and 2): List of all the coating compositions according to the
invention and comparative examples with the content of surfactants,
adhesion promoter additive and auxiliary solvents.
Part 1

| Batch/ | | | | Adhesion |
|---|---|---|---|---|
| coating | | | | promoter |
| composition | Type | Composition | Surfactant | additive |
| Org. solv.; | organic | PEDOT:PSS <0.7% | TEGO | DCB¹⁾ |
| surfactant; | | stock dispersion | TWIN 4000 | |
| adhesion | | | | |
| promoter: Ia | | | | |
| Org. solv.; | organic | PEDOT:PSS <0.7% | TEGO | DCB¹⁾ |
| surfactant; | | stock dispersion | TWIN 4000 | |
| adhesion | | | | |
| promoter: Ib | | | | |
| Org. solv.; | organic | PEDOT:PSS 0.7% | TEGO | — |
| surfactant: II | | stock dispersion | TWIN 4000 | |
| Org. solv.: III | organic | PEDOT:PSS 0.7% | none | — |
| | | stock dispersion | | |
| Comparative | aqueous | PEDOT:PSS 1% | none | — |
| example a) | | water 99% | | |
| Comparative | aqueous | PEDOT:PSS 1% | TEGO | — |
| example b) | | water >98% | TWIN 4000 | |

Part 2

| | | Adhesion | | Auxiliary |
|---|---|---|---|---|
| Batch/ | Surfactant | promoter | | solvent |
| coating | conc. | additive conc. | Auxiliary | conc. |
| composition | [wt. %] | [wt. %] | solvent | [wt. %] |
| Org. solv.; | 0.3 | 5 | IPA²⁾ | 5 |
| surfactant; | | | | |
| adhesion | | | | |
| promoter: Ia | | | | |
| Org. solv.; | 0.3 | 15 | IPA²⁾ | 15 |
| surfactant; | | | | |
| adhesion | | | | |
| promoter: Ib | | | | |
| Org. solv.; | 0.3 | 0 | — | 0 |
| surfactant: II | | | | |
| Org. solv.: III | 0 | 0 | — | 0 |
| Comparative | 0 | 0 | — | 0 |
| example a) | | | | |
| Comparative | 0.3 | 0 | — | 0 |
| example b) | | | | |

¹⁾DCB = dichlorobenzene
²⁾IPA = iso-propanol

In the investigation of the superficial dissolving properties, for coating composition Ia according to the invention with 5 wt. % of adhesion promoter additive a slight selective superficial dissolving of the PCBM (400 nm) in the P3HT:PCBM layer was found after 3 min (see Table 3). A reduction in the absorption of >1% was evaluated as a superficial dissolving process. In order to illustrate the effect of the superficial dissolving further, a longer action time of 10 min and a coating composition Ib of increased adhesion promoter additive concentration of 15 wt. % were chosen. In this case, a clear change in colour and intensity was to be found even with the naked eye, which thus clearly lies above a 1% reduction in absorption. In all cases PCBM is dissolved out to a much greater extent than the P3HT, and this selective process can be of advantage for use in an inverted OPV cell in this case. Coating compositions II and III without adhesion promoter additive and the aqueous comparative examples a) and b), on the other hand, showed no superficial dissolving properties.

TABLE 3
Superficial dissolving properties compared for PCBM after
an action time of 3 and 10 min by a reduction in the absorption
at the characteristic wavelengths of 400 nm.

| | | Adhesion | Classification | Classification |
|---|---|---|---|---|
| | | promoter | after 3 min/ | after 10 min/ |
| Batch/ | Adhesion | additive | reduction in | reduction in |
| coating | promoter | conc. | absorption at | absorption at |
| composition | additive | wt. % | 400 nm/% | 400 nm/% |
| Ia | DCB¹⁾ | 5 | 1.2 | 2.6 |
| Ib | DCB¹⁾ | 15 | 4.3 | 13.3 |
| II | — | 0 | <1 | <1 |
| III | — | 0 | <1 | <1 |
| Comparative | — | 0 | <1 | <1 |
| example a) | | | | |
| Comparative | — | 0 | <1 | <1 |
| example b) | | | | |

TABLE 4
Wettability of the active layer and adhesion
of the conductive polymer layer.

| Batch/ | Contact angle on the | | “Cross-cut tape” test |
|---|---|---|---|
| coating | active layer | Layer | (D 3359-08) |
| composition | (P3HT:PCBM) | producibility | Class/area removed |
| Ia | 21 | ++ | 5B/0% |
| II | 24 | 0 | 1B/35-65% |
| III | 54 | 0 | 1B/35-65% |
| Comparative | 100 | −− | not possible |
| example a) | | | |
| Comparative | 64 | − | 0B/>65% |
| example b) | | | |

++ = defect-free, homogeneous layer;
+ = homogeneous layer with <30 area % hole defects in the layer;
0 = homogeneous layer with more than 30 to 60 area % hole defects in the layer;
− = more than 60 area % hole defects in the layer;
−− = no layer formation - beading

Table 4 shows that coating compositions Ia, II and III according to the invention show a detectably better layer formation than comparative example a), the organic type Ia with the adhesion promoter additive and the auxiliary solvent resulting in the best layer. A better wetting with a lower contact angle on the active layer of <45° and for coating composition Ia and II of <30° was furthermore clearly to be seen. The contact angle of coating composition III is detectably below that of comparative examples a) and b). This underlines the better coating properties of the organic coating composition III according to the invention compared with the aqueous comparative examples a) and b).

During testing of the adhesion in the “cross-cut tape” test (see Table 4) with the adhesive tape (3M Post-it), no detachment at all was to be found with coating composition Ia with adhesion promoter additive, which is therefore class 5B/0%.

In the case of coating composition II and III without adhesion promoter additive and comparative example b), on the other hand, 35-65% of the squares or area of the layer was detached from the P3HT:PCBM, and these are therefore class 1B/35-65%. The test was possible only for compositions which form a homogeneous, closed layer.

It was therefore possible to clearly show that by addition of the non-polar solvent dichlorobenzene as an adhesion promoter additive to the non-aqueous PEDOT:PSS dispersion in coating composition Ia according to the invention, an improvement in the adhesion of the PEDOT:PSS layer to the P3HT:PCBM layer can be achieved. The superiority of coating compositions II and III according to the invention over comparative examples a) and b) also emerges clearly from this.

TABLE 5
OPV characteristic data of cells with coating composition Ia
according to the invention with adhesion promoter additive
in cell Ia, coating composition III according to the invention
without surfactant and adhesion promoter additive in
cell III and the aqueous comparative example b) in cell b).

| | PEDOT:PSS | Active | | | | |
|---|---|---|---|---|---|---|
| | type coating | area/ | V_{OC} | J_{SC} | | |
| OPV cell | composition | cm² | [V] | [mA cm⁻²] | FF | Eff. % |
| Cell Ia | Ia | 0.049 | 0.52 | 9.96 | 0.64 | 3.39 |
| Cell III | III | 0.049 | 0.53 | 7.32 | 0.63 | 2.48 |
| Cell b) | Comparative | 0.049 | 0 | 0 | 0 | 0 |
| | example b) | | | | | |

OPV cells could be produced from coating compositions Ia and III according to the invention. Coating compositions a) and b), which are not according to the invention, were not suitable for the production of an OPV cell. Even with coating composition b), which is not according to the invention, as an aqueous system with surfactant it was not possible to produce an OPV cell. On the other hand, this was successful with coating composition III according to the invention comprising organic solvent and no surfactant.

### LIST OF REFERENCE SYMBOLS

1 Layered body
2,2′ Conductive layer comprising conductive polymer (e.g. PEDOT:PSS)
3,3′ Photoactive layer (e.g. P3HT:PCBM)
4,4′ Intermediate layer
5 Organic photovoltaic cell
6 Hole contact or hole collecting electrode (e.g. silver layer)
7 Electron transport layer (e.g. zinc oxide or titanium oxide)
8 Electron contact or electron collecting electrode (consumer v. source) (e.g. ITO, TCO=transparent conductive oxide)
9 Substrate
10 Adhesive tape

What is claimed is:

1. A process for the production of a layered body, the process comprising the steps:
I) providing a photoactive layer;
II) superimposing the photoactive layer with a coating composition comprising
a) an electrically conductive polymer,
b) an organic solvent) and
III) at least partially removing the organic solvent b) from the coating composition superimposed in process step II) to obtain an electrically conductive layer superimposed on the photoactive layer.

2. The process of claim 1, wherein the coating composition further comprises a surfactant c).

3. The process of claim 2, wherein the coating composition further comprises an adhesion promoter additive d) that is a further organic solvent which differs from component b) and component c) and is miscible with component b), wherein the photoactive layer is soluble in the adhesion promoter additive.

4. The process of claim 1, wherein the photoactive layer is a non-polar layer.

5. The process of claim 1, wherein the photoactive layer comprises hydrophobic compounds which are a mixture of poly-3-hexylthiophene and phenyl-C61-butyric acid-methyl ester (P3HT:PCBM).

6. The process of claim 1, wherein the electrically conductive polymer a) is a cationic polythiophene, which is present in the form of ionic complexes of the cationic polythiophene and a polymeric anion as the counter-ion.

7. The process of claim 1, wherein the conductive polymer a) is present in the form of ionic complexes of poly(3,4-ethylenedioxythiophene) and polystyrenesulphonic acid (PEDOT:PSS).

8. The process of claim 1, wherein the organic solvent b) is selected from the group consisting of methanol, ethanol, 1-propanol, 2-propanol, 1,2-propanediol, 1,3-propanediol, ethylene glycol, diethylene glycol, propylene glycol, dipropylene glycol, glycerol, and mixtures of two or more thereof.

9. The process of claim 2, wherein the surfactant c) is a nonionic surfactant.

10. The process claim 3, wherein the adhesion promoter additive d) is an aromatic compound in which one or more hydrogen atoms can optionally be replaced by halogen atoms.

11. The process of claim 3, wherein the adhesion promoter additive d) is selected from the group consisting of acetone, xylene, styrene, anisole, toluene, nitrobenzene, benzene, cyclohexane, tetrahydrofuran, chloronaphthalene, chlorobenzene, derivatives thereof, and mixtures of two or more thereof.

12. The process of claim 1, wherein the coating composition of step II) is obtained by a process comprising the steps:
IIa) providing a composition A comprising the conductive polymer a) and the organic solvent b);
IIb) providing a composition B comprising the surfactant c) and a first auxiliary solvent;
IIc) providing a composition C comprising the adhesion promoter additive d) and a second auxiliary solvent;
IId) mixing compositions A, B and C in any desired sequence.

13. The process of claim 3, wherein the coating composition of step II) comprises, in each case based on the total weight of the composition:
0.4 to 1 wt. % of the conductive polymer a);
78 to 96 wt. % of the organic solvent b);
0.1 to 1.1 wt % of the surfactant c);
1 to 15 wt % of the adhesion promoter additive d); and
0 to 15 wt. % of one or more auxiliary substances.

14. The process of claim 1, wherein the coating composition of step II) comprises, based on the total weight of the coating composition, less than 6 wt. % of water.

15. A layered body obtained by the process of claim 1.

16. The layered body of claim 15, comprising
i) the photoactive layer comprising at least one hydrophobic compound;
ii) the conductive layer comprising a conductive polymer and superimposed on the photoactive layer; and
iii) an intermediate layer located between the photoactive layer and the conductive layer, the intermediate layer comprising a mixture of the conductive polymer and the at least one hydrophobic compound.

17. The layered body of claim 16, wherein the photoactive layer comprises less conductive polymer from the conductive layer than the intermediate layer and the conductive layer comprises less of the at least one hydrophobic compound from the photoactive layer than the intermediate layer.

18. A layered body, comprising:
i) a photoactive layer comprising at least one hydrophobic compound;
ii) a conductive layer comprising a conductive polymer and is superimposed on the photoactive layer; and
iii) an intermediate layer located between the photoactive layer and the conductive layer and comprising a mixture of the conductive polymer and the at least one hydrophobic compound from.

19. The layered body of claim 18, wherein the photoactive layer comprises less conductive polymer than the intermediate layer and the conductive layer comprises less of the at least one hydrophobic compound from than the intermediate layer.

20. The layered body of claim 18, wherein the photoactive layer is a non-polar layer.

21. The layered body of claim 18, wherein the photoactive layer comprises hydrophobic compounds which are a mixture of poly-3-hexylthiophene and phenyl-C61-butyric acid-methyl ester (P3HT:PCBM).

22. The layered body of claim 15, wherein the conductive polymer a) in the coating composition of step II) is a cationic polythiophene, which is present in the form of ionic complexes of the cationic polythiophene and a polymeric anion as the counter-ion.

23. The layered body of claim 22, wherein the conductive polymer is present in the form of ionic complexes of poly(3,4-ethylenedioxythiophene) and polystyrenesulphonic acid (PEDOT:PSS).

24. The layered body of claim 23, wherein the area of the conductive layer removed in the “cross-cut tape test” is less than 5%.

25. An organic photovoltaic cell comprising the layered body of claim 15.

26. The organic photovoltaic cell of claim 25, comprising
a. an anode;
b. the layered body;
c. optionally, an electron transport layer; and
d. a cathode.

27. A solar cell module, comprising at least one organic photovoltaic cell of claim 25.

28. A composition comprising, based on the total weight of the composition:
0.4 to 0.7 wt. % of PEDOT:PSS;
78 to 96 wt. % of an organic solvent selected from the group consisting of ethylene glycol, propanediol, ethanol, and mixtures of two or more thereof;
0.1 to 1.1 wt % of a surfactant;
1 to 15 wt. % of an adhesion promoter additive selected from the group consisting of xylene, toluene, styrene, anisole, cyclohexane, tetrahydrofuran, chlorobenzene, dichlorobenzene, and mixtures of two or more thereof; and
0 to 15 wt. % of one or more auxiliary substances.

29. The composition of claim 28, wherein the composition comprises less than 6 wt. % of water.

30. A P3HT:PCBM layer having a conductive layer comprising the composition of claim 28.

31. The composition of claim 28, wherein the weight of PEDOT:PSS is in a range of from 1:2 to 1:6.

32. A conductive film formed from the composition of claim 28, wherein the conductive film has a specific resistance of less than 10,000 Ω·cm.
